(19) United States
(12) Patent Application Publication
(10) Pub. No.: US 2025/0006849 A1
(43) Pub. Date: Jan. 2, 2025

(54) SEMICONDUCTOR DEVICE AND MANUFACTURING METHOD FOR SEMICONDUCTOR DEVICE

(71) Applicant: ROHM CO., LTD., Kyoto-shi (JP)

(72) Inventors: Ryo YOSHIDA, Kyoto-shi (JP); Yuto TAKIGAWA, Kyoto-shi (JP)

(21) Appl. No.: 18/882,110

(22) Filed: Sep. 11, 2024

Related U.S. Application Data
(63) Continuation of application No. PCT/JP2023/010366, filed on Mar. 16, 2023.

(30) Foreign Application Priority Data
Mar. 18, 2022 (JP) 2022-043968
Mar. 18, 2022 (JP) 2022-043969

(51) Int. Cl. H01L 29/872; H01L 21/265; H01L 21/266; H01L 29/66

(52) U.S. Cl. CPC H01L 29/8725; H01L 21/26513; H01L 21/266; H01L 29/66143

(57) ABSTRACT

This semiconductor device comprises a semiconductor substrate of a first conductivity type, a semiconductor layer of the first conductivity type, a first electrode, a second electrode, a first trench, a second trench, an insulating layer, a third electrode, and a well region of a second conductivity type. The well region includes a first region that is adjacent to the first trench, a second region that is adjacent to the second trench, and a third region that is located between the first region and the second region in a second direction. The impurity concentration of the first region and the impurity concentration of the second region are both lower than the impurity concentration of the third region.

### BACKGROUND

The present disclosure relates to a semiconductor device and a method for manufacturing a semiconductor device.

A known semiconductor device includes a semiconductor substrate, a semiconductor layer formed on the semiconductor substrate, an anode electrode formed on the semiconductor layer, a cathode electrode formed on a side of the semiconductor substrate opposite from the semiconductor layer (for example, refer to JP 2012-124329 A).

### BRIEF DESCRIPTION OF DRAWINGS

FIG. 1 is a schematic plan view showing an embodiment of a semiconductor device.

FIG. 2 is a schematic plan view showing a semiconductor layer of the semiconductor device shown in FIG. 1.

FIG. 3 is a schematic cross-sectional view showing the semiconductor device taken along line F3-F3 in FIG. 1.

FIG. 4 is an enlarged cross-sectional view schematically showing two trenches and their surroundings shown in FIG. 3.

FIG. 5 is an enlarged cross-sectional view schematically showing a well region and its surroundings shown in FIG. 4.

FIG. 6 is a schematic cross-sectional view showing a manufacturing step of a semiconductor device.

FIG. 7 is a schematic cross-sectional view showing a manufacturing step subsequent to FIG. 6.

FIG. 8 is a schematic cross-sectional view showing a manufacturing step subsequent to FIG. 7.

FIG. 9 is a schematic cross-sectional view showing a manufacturing step subsequent to FIG. 8.

FIG. 10 is a schematic cross-sectional view showing a manufacturing step subsequent to FIG. 9.

FIG. 11 is a schematic cross-sectional view showing a manufacturing step subsequent to FIG. 10.

FIG. 12 is a schematic cross-sectional view showing a manufacturing step subsequent to FIG. 11.

FIG. 13 is a schematic cross-sectional view showing a manufacturing step subsequent to FIG. 12.

FIG. 14 is a schematic cross-sectional view showing a manufacturing step subsequent to FIG. 13.

FIG. 15 is a schematic cross-sectional view showing a manufacturing step subsequent to FIG. 14.

FIG. 16 is an enlarged cross-sectional view schematically showing two trenches and their surroundings in a first comparative example of a semiconductor device.

FIG. 17 is an enlarged cross-sectional view schematically showing two trenches and their surroundings in a second comparative example of a semiconductor device.

FIG. 18 is an enlarged cross-sectional view schematically showing two trenches and their surroundings in a second embodiment of a semiconductor device.

FIG. 19 is an enlarged cross-sectional view schematically showing two trenches and their surroundings in a third embodiment of a semiconductor device.

FIG. 20 is a graph showing the relationship between the forward voltage drop and the forward current of semiconductor devices in the first embodiment, the third embodiment, and the first comparative example.

FIG. 21 is a graph showing the relationship between the reverse voltage and the reverse current of the semiconductor devices in the first embodiment, the third embodiment, and the first comparative example.

FIG. 22 is a graph showing the relationship between the forward voltage drop and the reverse current of the semiconductor devices in the first to third embodiments, the first comparative example, and the second comparative example.

FIG. 23 is a graph showing the relationship between the forward voltage drop and the forward current of semiconductor devices in the first embodiment, a fourth embodiment, and the first comparative example.

FIG. 24 is a graph showing the relationship between the reverse voltage and the reverse current of the semiconductor devices in the first embodiment, the fourth embodiment, and the first comparative example.

FIG. 25 is an enlarged schematic cross-sectional view showing two trenches and their surroundings in the fourth embodiment of the semiconductor device.

FIG. 26 is an enlarged cross-sectional view schematically showing two trenches and their surroundings in a modified example of a semiconductor device.

FIG. 27 is an enlarged cross-sectional view schematically showing two trenches and their surroundings in a modified example of a semiconductor device.

FIG. 28 is a cross-sectional view schematically showing a modified example of a semiconductor device.

FIG. 29 is an enlarged perspective cross-sectional view schematically showing two trenches and their surroundings of the semiconductor device shown in FIG. 28.

FIG. 30 is an enlarged cross-sectional view schematically showing two trenches and their surroundings of the semiconductor device shown in FIG. 28.

### DETAILED DESCRIPTION

Embodiments of a semiconductor device according to the present disclosure will now be described with reference to the accompanying drawings. In the drawings, elements may not be drawn to scale for simplicity and clarity of illustration. In a cross-sectional view, hatching may be omitted to facilitate understanding. The accompanying drawings only illustrate embodiments of the present disclosure and are not intended to limit the present disclosure.

The following detailed description includes exemplary embodiments of a device, a system, and a method according to the present disclosure. The detailed description is illustrative and is not intended to limit embodiments of the present disclosure or the application and use of the embodiments.

### General Configuration of Semiconductor Device

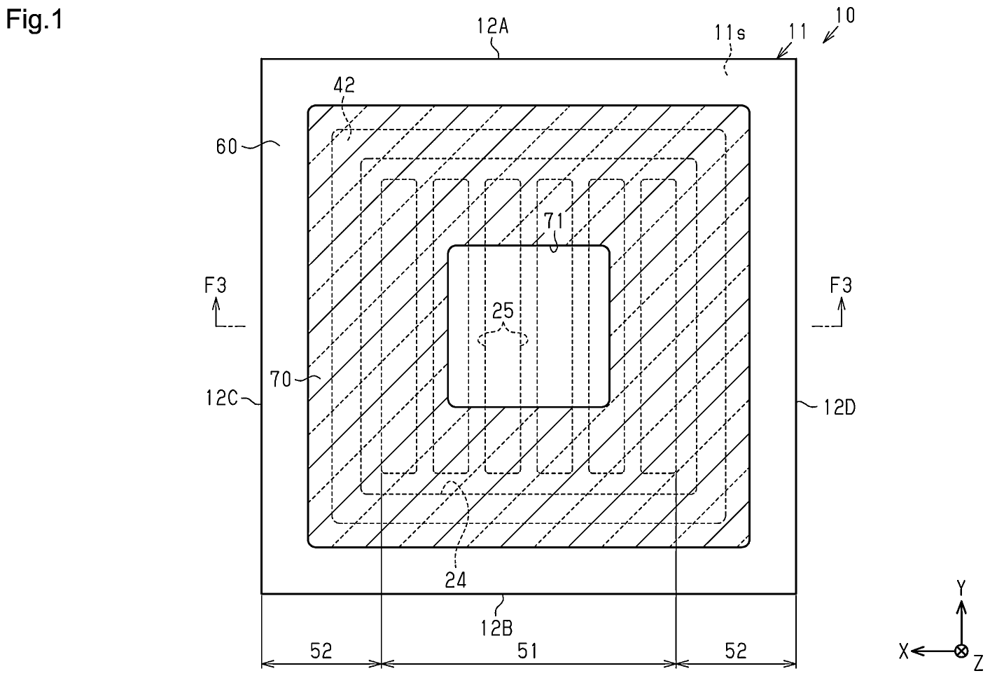

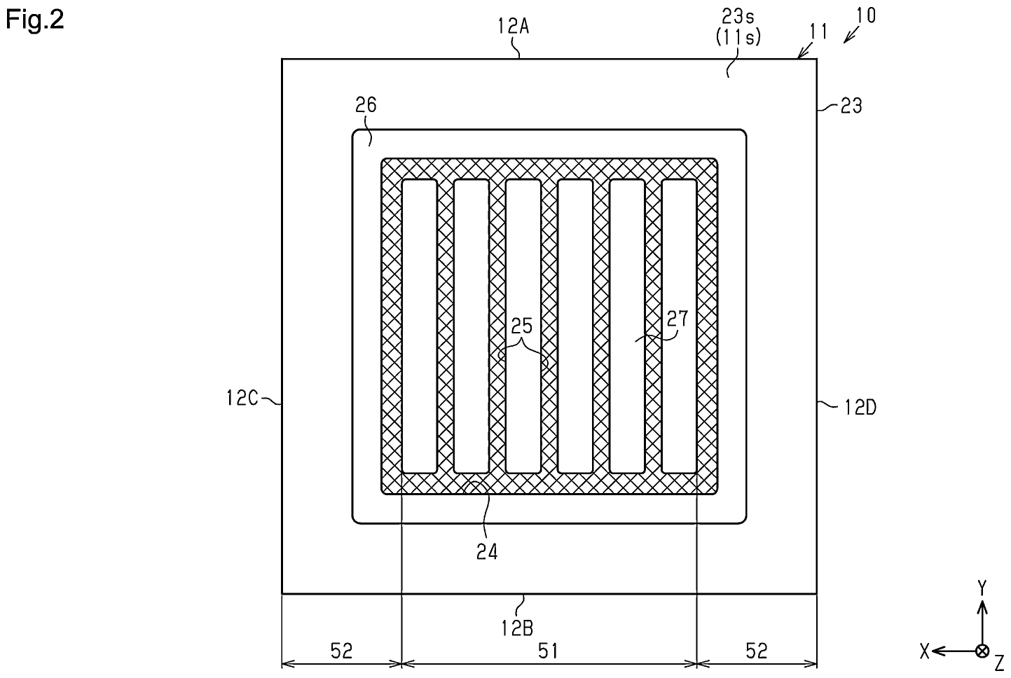

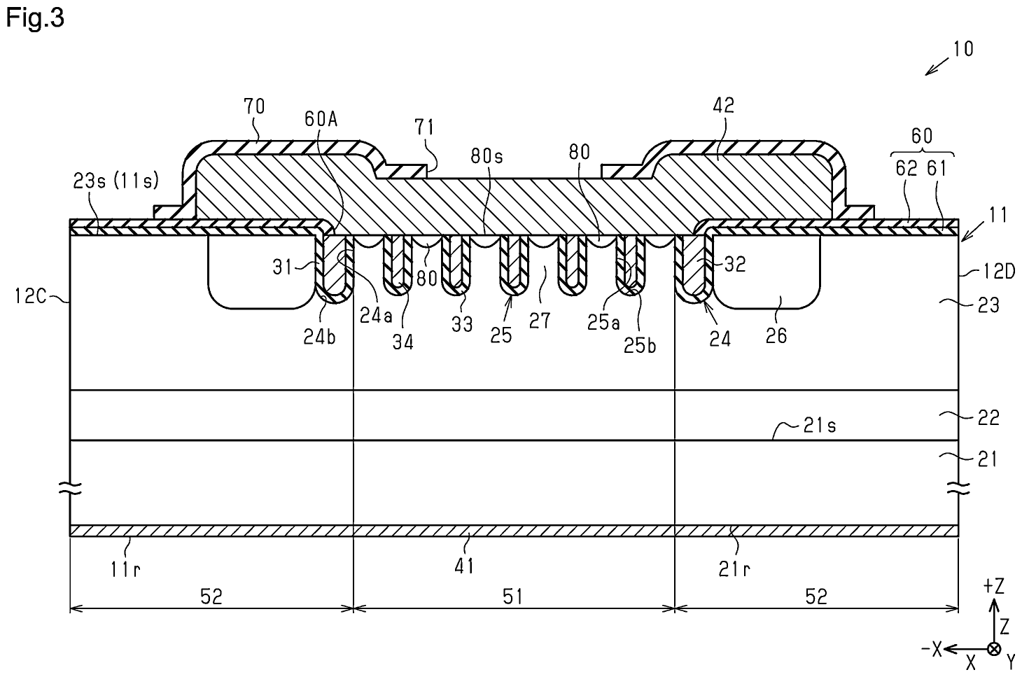

General configurations of a semiconductor device 10 according to the present embodiment will be described with reference to FIGS. 1 to 3. FIG. 1 schematically shows a planar structure of the semiconductor device 10. FIG. 2 schematically shows a planar structure showing a semiconductor chip 11, which will be described later, of the semiconductor device 10 shown in FIG. 1. FIG. 3 schematically shows a cross-sectional structure taken along line F3-F3 in FIG. 1. In FIG. 1, to facilitate understanding, a surface protection layer 70 is indicated by hatching lines for glass and will be described later. In FIG. 2, to facilitate understanding, an isolation trench 24 and trenches 25 are indicated by cross-hatching lines and will be described later. For the sake of convenience, FIG. 3 partially does not show hatching lines of the semiconductor device 10.

The X-axis, Y-axis, and Z-axis are orthogonal to one another as shown in FIG. 3. The term “plan view” as used in the present disclosure is a view of the semiconductor device 10 taken in the Z-axis direction. Further, in the semiconductor device 10A shown in FIG. 3, the +Z direction corresponds to the upward direction, the −Z direction corresponds to the downward direction, the +X direction corresponds to the rightward direction, and the −X direction corresponds to the leftward direction. The term “plan view” will refer to a view taken from above along the Z-axis of the semiconductor device 10 unless otherwise indicated.

The semiconductor device 10 is a semiconductor rectifier. As shown in FIG. 1, the semiconductor device 10 includes the semiconductor chip 11. The semiconductor chip 11 is formed from, for example, a material containing silicon (Si). The material forming the semiconductor chip 11 is not limited to Si and may be any material. In the present embodiment, the semiconductor chip 11 has the form of a flat plate. The semiconductor chip 11 includes a chip front surface 11s and a chip back surface 11r (refer to FIG. 3). The semiconductor chip 11 further includes first to fourth chip side surfaces 12A and 12D connecting the chip front surface 11s and the chip back surface 11r.

The shape of the semiconductor chip 11 in plan view, that is, the shape of the chip front surface 11s and the chip back surface 11r in plan view, is a rectangle. The first chip side surface 12A and the second chip side surface 12B extend in the X-axis direction. The third chip side surface 12C and the fourth chip side surface 12D extend in the Y-axis direction. The first chip side surface 12A and the second chip side surface 12B are opposed to each other in the Y-axis direction. The third chip side surface 12C and the fourth chip side surface 12D are opposed to each other in the X-axis direction.

As shown in FIG. 3, the semiconductor device 10 includes a semiconductor substrate 21 located at a side of the chip back surface 11r of the semiconductor chip 11. The semiconductor substrate 21 includes a substrate front surface 21s and a substrate back surface 21r opposite to the substrate front surface 21s. The substrate front surface 21s faces the same direction as the chip front surface 11s. The substrate back surface 21r faces the same direction as the chip back surface 11r.

The semiconductor substrate 21 has an electrical resistivity, for example, in a range of 0.5 mΩ·cm to 3 mΩ·cm. The semiconductor substrate 21 has an n-type impurity concentration, for example, in a range of 1×10¹⁸ cm⁻³ to 1×10²¹ cm⁻³. The semiconductor substrate 21 has a thickness in a range of 5 μm to 300 μm. In an example, the thickness of the semiconductor substrate 21 is in a range of 50 μm to 300 μm. In the present embodiment, the semiconductor substrate 21 is formed of an n-type semiconductor substrate. The semiconductor substrate 21 is, for example, a Si substrate. The material forming the semiconductor substrate 21 is not limited to Si and may be any material. In an example, the material forming the semiconductor substrate 21 may be silicon carbide (SIC).

The semiconductor device 10 includes a cathode electrode 41 formed on the substrate back surface 21r of the semiconductor substrate 21. The cathode electrode 41 is formed on the entirety of the substrate back surface 21r. The cathode electrode 41 is electrically connected to the semiconductor substrate 21. The cathode electrode 41 is in ohmic contact with the semiconductor substrate 21 (substrate back surface 21r). The cathode electrode 41 includes the chip back surface 11r. In the present embodiment, the cathode electrode 41 corresponds to a “second electrode.”

The cathode electrode 41 has a stacking structure formed of multiple metal films. In an example, the cathode electrode 41 has a structure in which a first metal film, a second metal film, and a third metal film are stacked sequentially from the substrate back surface 21r.

The first metal film is formed from a material containing, for example, titanium (Ti). The first metal film has a thickness in a range of, for example, 500 angstroms to 2000 angstroms. The second metal film is formed from a material containing, for example, nickel (Ni). The second metal film has, for example, a greater thickness than the first metal film. The second metal film has a thickness in a range of, for example, 2000 angstroms to 6000 angstroms. The third metal film is formed from a material containing, for example, gold (Au). The third metal film has, for example, a smaller thickness than the second metal film. The third metal film has, for example, a smaller thickness than the first metal film. The third metal film has a thickness in a range of, for example, 100 angstroms to 1000 angstroms. The cathode electrode 41 may include a fourth metal film arranged between the second metal film and the third metal film. The fourth metal film is formed from a material containing, for example, palladium (Pd).

The semiconductor device 10 includes an n-type buffer layer 22 formed on the semiconductor substrate 21 and an n-type drift layer 23 formed on the buffer layer 22. The drift layer 23 is formed on the semiconductor substrate 21 with the buffer layer 22 located in between. In other words, the drift layer 23 is formed on the semiconductor substrate 21. In the present embodiment, the drift layer 23 corresponds to a “semiconductor layer.” The n-type corresponds to a “first conductive type.”

The buffer layer 22 is in contact with the substrate front surface 21s of the semiconductor substrate 21. The buffer layer 22 is formed on the entirety of the substrate front surface 21s. The buffer layer 22 has a concentration gradient in which the concentration of n-type impurity decreases upward from the semiconductor substrate 21. The buffer layer 22 has a thickness in a range of 1 μm to 10 μm. In the present embodiment, the buffer layer 22 is formed of an n-type epitaxial layer (Si epitaxial layer).

The drift layer 23 is in contact with the buffer layer 22. The drift layer 23 includes a front surface 23s facing the same direction as the chip front surface 11s. In the present embodiment, the front surface 23s of the drift layer 23 defines the chip front surface 11s. In plan view, the drift layer 23 is formed on the entirety of the buffer layer 22. The drift layer 23 is lower in n-type impurity concentration than the semiconductor substrate 21. The n-type impurity concentration of the drift layer 23 is, for example, in a range of 1×10¹⁵ cm⁻³ to 1×10¹⁶ cm⁻³. The drift layer 23 has an electrical resistivity, for example, in a range of 1.0 Ω·cm to 4.0 Ω·cm. The drift layer 23 has a thickness in a range of 6 μm to 20 μm. In the present embodiment, the drift layer 23 is formed of an n-type epitaxial layer (Si epitaxial layer).

As shown in FIGS. 1 and 2, the semiconductor device 10 includes the isolation trench 24 extending from the front surface 23s of the drift layer 23 in the Z-axis direction. In plan view, the isolation trench 24 is located inward from the first to fourth chip side surfaces 12A to 12D. The isolation trench 24 is annular in plan view. In the present embodiment, the shape of the isolation trench 24 in plan view is a rectangular frame. In plan view, the isolation trench 24 separates an active region 51, which is an inner region of the isolation trench 24, and a peripheral region 52, which is an outer region of the isolation trench 24. The shape of the isolation trench 24 in plan view may be changed in any manner.

The active region 51 is a region in which a diode is formed. The active region 51 is rectangular in plan view. The peripheral region 52 is a region in which no diode is formed. The peripheral region 52 has, for example, a terminal structure for improving the breakdown voltage. In plan view, the peripheral region 52 is annular and surrounds the active region 51.

As shown in FIG. 3, the isolation trench 24 includes two side walls 24a and bottom wall 24b joining the two side walls 24a. The isolation trench 24 is formed in the drift layer 23. Thus, the bottom wall 24b of the isolation trench 24 is located above the buffer layer 22. In the present embodiment, the bottom wall 24b is bulged toward the buffer layer 22 in a curved manner. The shape of the bottom wall 24b may be changed in any manner.

The semiconductor device 10 includes an isolation insulation film 31 and an isolation electrode 32 arranged in the isolation trench 24.

The isolation insulation film 31 extends along the two side walls 24a and the bottom wall 24b of the isolation trench 24. The isolation insulation film 31 is formed from a material including, for example, silicon oxide (SiO₂). The isolation insulation film 31 has a thickness, for example, in a range of 0.05 μm to 0.5 μm. The isolation insulation film 31 may have a thickness in a range of 0.1 μm to 0.4 μm. The isolation insulation film 31 defines a recessed space in the isolation trench 24.

The isolation electrode 32 fills the recessed space of the isolation trench 24. In other words, the isolation electrode 32 is embedded in the isolation trench 24 sandwiching the isolation insulation film 31. The isolation electrode 32 includes, for example, a conductive polysilicon. The conductive polysilicon may be an n-type polysilicon or a p-type polysilicon.

As shown in FIGS. 1 to 3, multiple (in the present embodiment, five) trenches 25 are formed in the active region 51. That is, the semiconductor device 10 includes the trenches 25. Each trench 25 extends from the front surface 23s of the drift layer 23 in the Z-axis direction and the Y-axis direction. In the present embodiment, in plan view, the trench 25 is linear and extends in the Y-axis direction. The trenches 25 are separated from each other in the X-axis direction. In other words, in plan view, the trenches 25 are arranged in a stripe pattern. The trenches 25 are each in communication with the isolation trench 24 in the Y-axis direction. In the present embodiment, the Y-axis direction corresponds to a “first direction.” The X-axis direction corresponds to a “second direction.” The trenches 25 may be separated from the isolation trench 24. That is, the trenches 25 do not necessarily have to be in communication with the isolation trench 24

As shown in FIG. 3, the trenches 25 each include two side walls 25a and a bottom wall 25b joining the two side walls 25a. The trenches 25 are arranged in the drift layer 23. Thus, the bottom walls 25b of the trenches 25 are located above the buffer layer 22. In the present embodiment, the bottom wall 25b is bulged toward the buffer layer 22 in a curved manner. The shape of the bottom wall 25b may be changed in any manner.

In the present embodiment, the trench 25 has a smaller depth than the isolation trench 24. In other words, the isolation trench 24 has a greater depth than the trenches 25. The trench 25 and the isolation trench 24 may have the same depth. In an example, the depth of the isolation trench 24 may be in a range of 1 μm to 5 μm. The depth of the isolation trench 24 may be, for example, in a range of 1.5 μm to 3 μm. The depth of the trench 25 may be, for example, in a range of 1 μm to 5 μm. The depth of the trench 25 may be, for example, in a range of 0.8 μm to 2 μm. The isolation trench 24 and the trench 25 are separated from the bottom (the buffer layer 22) of the drift layer 23 by 1 μm or greater (preferably, 3 μm or greater).

The trench 25 has a smaller width than the isolation trench 24. In other words, the isolation trench 24 has a greater width than the trench 25. In an example, the width of the isolation trench 24 may be in a range of 0.5 μm to 3 μm. The width of the isolation trench 24 may be, for example, in a range of 0.8 μm to 1.5 μm. The width of the trench 25 may be, for example, in a range of 0.1 μm to 2 μm. The width of the trench 25 may be, for example, in a range of 0.4 μm to 1.2 μm.

The width of the isolation trench 24 refers to the dimension of the isolation trench 24 in a direction orthogonal to a direction in which the isolation trench 24 extends in plan view. The width of the trench 25 refers to the dimension of the trench 25 in a direction orthogonal to a direction in which the trench 25 extends in plan view. In the present embodiment, in plan view, the trench 25 extends in the Y-axis direction. Thus, the width of the trench 25 refers to the dimension of the trench 25 in the X-axis direction in plan view.

The distance between two trenches 25 located adjacent to each other in the X-axis direction may be, for example, in a range of 1 μm to 5 μm. The distance between two trenches 25 located adjacent to each other in the X-axis direction may be in a range of 2 μm to 4 μm. The distance from trenches 25 located at opposite ends in the X-axis direction to the isolation trench 24 that is located adjacent to the trenches 25 in the X-axis direction is substantially the same as the distance between two trenches 25 located adjacent to each other in the X-axis direction.

The semiconductor device 10 includes an insulation layer 33 and an embedded electrode 34 arranged in each trench 25. In the present embodiment, the embedded electrode 34 corresponds to a “third electrode.”

The insulation layer 33 extends along the two side walls 25a and the bottom wall 25b of the trench 25. The insulation layer 33 is connected to the isolation insulation film 31 in a portion of the trench 25 that is in communication with the isolation trench 24. The insulation layer 33 is formed from a material including, for example, SiO₂. The insulation layer 33 has a thickness, for example, in a range of 0.05 μm to 0.5 μm. The insulation layer 33 may have a thickness in a range of 0.1 μm to 0.4 μm. The thickness of the isolation insulation film 31 is, for example, greater than or equal to the thickness of the insulation layer 33. The insulation layer 33 defines a recessed space in the trench 25.

The embedded electrode 34 fills the recessed space of the trench 25. In other words, the embedded electrode 34 is embedded in the trench 25 sandwiching the insulation layer 33. The embedded electrode 34 is connected to the isolation electrode 32 in a portion of the trench 25 that is in communication with the isolation trench 24. The embedded electrode 34 includes, for example, a conductive polysilicon. The conductive polysilicon may be an n-type polysilicon or a p-type polysilicon.

The semiconductor device 10 includes a p-type peripheral well region 26 formed in a surface portion of the drift layer 23 along the isolation trench 24 in the peripheral region 52. In the present embodiment, the p-type corresponds to a “second conductive type.”

The peripheral well region 26 is formed in the front surface 23s of the drift layer 23. As shown in FIG. 2, the peripheral well region 26 is annular in plan view. The peripheral well region 26 is an example of the termination structure and is formed to be electrically floating. Thus, the peripheral well region 26 is electrically separated from the isolation electrode 32 and the embedded electrode 34. The peripheral well region 26 has a p-type impurity concentration in a range of 1×10¹⁷ cm⁻³ to 1×10¹⁹ cm⁻³. As shown in FIG. 3, the p-type impurity concentration of the peripheral well region 26 has a concentration gradient that gradually decreases from the front surface 23s of the drift layer 23 toward the bottom (the buffer layer 22) of the drift layer 23.

In plan view, the peripheral well region 26 is arranged adjacent to the isolation trench 24. The peripheral well region 26 is in contact with the side wall 24a of the isolation trench 24.

In the present embodiment, the thickness of the peripheral well region 26 is greater than the depth of the isolation trench 24. The thickness of the peripheral well region 26 is also greater than the depth of the trench 25. The bottom of the peripheral well region 26 is separated from the bottom (the buffer layer 22) of the drift layer 23. In an example, the thickness of the peripheral well region 26 may be in a range of 1 μm to 5 μm. The thickness of the peripheral well region 26 may be changed in any manner. In an example, the thickness of the peripheral well region 26 may be less than the depth of the isolation trench 24. The peripheral well region 26 may be formed to cover a portion of the bottom wall 24b of the isolation trench 24.

The peripheral well region 26 is greater in width than the isolation trench 24. The peripheral well region 26 is greater in width than the trench 25. The width of the peripheral well region 26 is greater than the thickness of the peripheral well region 26. In an example, the width of the peripheral well region 26 may be in a range of 2 μm to 20 μm. In an example, the width of the peripheral well region 26 may be in a range of 5 μm to 15 μm. The width of the peripheral well region 26 is defined by the dimension of the peripheral well region 26 in a direction orthogonal to a direction in which the peripheral well region 26 extends in plan view.

The semiconductor device 10 includes a surface insulation layer 60 covering the front surface 23s of the drift layer 23 in the peripheral region 52. The surface insulation layer 60 is annular in plan view in conformance with the shape of the peripheral region 52. More specifically, the surface insulation layer 60 includes a through hole 60A exposing the active region 51. The surface insulation layer 60 includes an inner peripheral edge that overlaps a portion of the isolation electrode 32 in plan view. That is, the surface insulation layer 60 covers a portion of the upper surface of the isolation electrode 32. The surface insulation layer 60 covers the entirety of the peripheral well region 26. Thus, the peripheral well region 26 is insulated from the outside.

The surface insulation layer 60 has a stacking structure including a first insulation film 61 and a second insulation film 62.

The first insulation film 61 is in contact with the front surface 23s of the drift layer 23. The first insulation film 61 is formed from a material including, for example, SiO₂. In an example, the first insulation film 61 is formed of a field oxide film including the oxide of the drift layer 23.

The second insulation film 62 is formed on the first insulation film 61. The second insulation film 62 includes a silicon oxide film that differs in property from the first insulation film 61. In an example, the second insulation film 62 may include at least one of a phosphorus silicate glass (PSG) film and an undoped silicate glass (USG) film. The PSG is a silicon oxide film including P. The USG film is a silicon oxide film that is impurity-free. The second insulation film 62 may have a stacking structure of a PSG film and a USG film.

The first insulation film 61 has a thickness in a range of 1000 angstroms to 5000 angstroms. The thickness of the first insulation film 61 may be in a range of 1500 angstroms to 3500 angstroms. The second insulation film 62 has a thickness in a range of 1000 angstroms to 6000 angstroms. The thickness of the second insulation film 62 may be in a range of 2500 angstroms to 4500 angstroms.

The semiconductor device 10 includes an anode electrode 42 formed on the front surface 23s of the drift layer 23. The anode electrode 42 corresponds to a “first electrode.”

The anode electrode 42 extends over the active region 51 and the peripheral region 52. More specifically, the anode electrode 42 extends over the entirety of the active region 51. As shown in FIG. 1, the anode electrode 42 is arranged inward from the first to fourth chip side surfaces 12A to 12D of the peripheral region 52 in plan view. In other words, the anode electrode 42 is arranged in an inner peripheral portion of the peripheral region 52. The shape of the anode electrode 42 is rectangular in plan view.

As shown in FIG. 3, the anode electrode 42 is in contact with the isolation electrode 32 and the embedded electrode 34. More specifically, the anode electrode 42 is in ohmic contact with the isolation electrode 32 and the embedded electrode 34. Thus, the anode electrode 42 is electrically connected to the isolation electrode 32 and the embedded electrode 34.

In the peripheral region 52, the anode electrode 42 is formed on the surface insulation layer 60. Thus, in the peripheral region 52, the anode electrode 42 is insulated from the drift layer 23 and the peripheral well region 26. In the present embodiment, the anode electrode 42 includes an outer peripheral edge located outward from the peripheral well region 26.

The anode electrode 42 has a stacking structure including, for example, a first electrode film, a second electrode film, and a third electrode film. The second electrode film is formed on the first electrode film. The third electrode film is formed on the second electrode film. The second electrode film is greater in thickness than the first electrode film. The third electrode film is greater in thickness than each of the first electrode film and the second electrode film. The thickness of the first electrode film may be in a range of, for example, 50 angstroms to 1000 angstroms. The thickness of the first electrode film may be in a range of, for example, 250 angstroms to 500 angstroms. The thickness of the second electrode film may be in a range of 500 angstroms to 5000 angstroms. The thickness of the second electrode film may be in a range of 1500 angstroms to 4500 angstroms. The thickness of the third electrode film may be in a range of 0.5 μm to 10 μm. The thickness of the third electrode film may be in a range of 2.5 μm to 7.5 μm.

The first electrode film may be formed from an electrode material including at least one of magnesium (Mg), aluminum (Al), titanium (Ti), vanadium (V), chromium (Cr), manganese (Mn), cobalt (Co), nickel (Ni), copper (Cu), zirconium (Zr), niobium (Nb), molybdenum (Mo), palladium (Pd), silver (Ag), indium (In), tin (Sn), tantalum (Ta), tungsten (W), platinum (Pt), and gold (Au). The first electrode film may be formed of a single film or multiple films that have a stacking structure. The multiple films each may be formed from a different electrode material. In the present embodiment, the first electrode film is formed from a material including Ti.

The second electrode film is a metal barrier film and is formed of, for example, a Ti-based metal film. The second electrode film may be formed from an electrode material including at least one of Ti and titanium nitride (TiN). The second electrode film may be formed of a single film formed of Ti or TiN. The second electrode film may be formed of a Ti film or a TiN film having a stacking structure. In the present embodiment, the second electrode film is formed from a material including TiN.

The third electrode film is configured to be an electrode pad and is formed from a material including Cu or Al. The electrode material of the third electrode film may include at least one of Cu, Al, an aluminum copper (AlCu) alloy, an aluminum silicon (AlSi) alloy, and an aluminum silicon copper (AlSiCu) alloy. In the present embodiment, the third electrode film is formed from a material including Al.

The semiconductor device 10 includes the surface protection layer 70 formed on the surface insulation layer 60 to cover the anode electrode 42.

As shown in FIG. 1, the surface protection layer 70 includes an outer peripheral edge located at a position separated from the first to fourth chip side surfaces 12A to 12D. As shown in FIG. 3, the surface protection layer 70 is formed continuously from the upper surface to the side surface of the anode electrode 42. The surface protection layer 70 extends outward beyond the anode electrode 42. The surface protection layer 70 includes an opening 71 exposing a central portion of the anode electrode 42. The portion of the anode electrode 42 exposed from the opening 71 is used as an electrode pad configured to be bonded to a connection member such as a wire.

The surface protection layer 70 has a single-layer structure formed of an inorganic insulation film. The surface protection layer 70 is formed of an insulator that differs from that of the surface insulation layer 60. In an example, the surface protection layer 70 may include at least one of SiN and silicon oxynitride (SiON). The surface protection layer 70 may have a thickness in a range of, for example, 0.2 μm to 1.5 μm. The surface protection layer 70 may have a thickness in a range of, for example, 0.6 μm to 1.2 μm. The surface protection layer 70 may be formed from an organic insulation film such as polyimide.

### Detailed Configuration Between Trenches

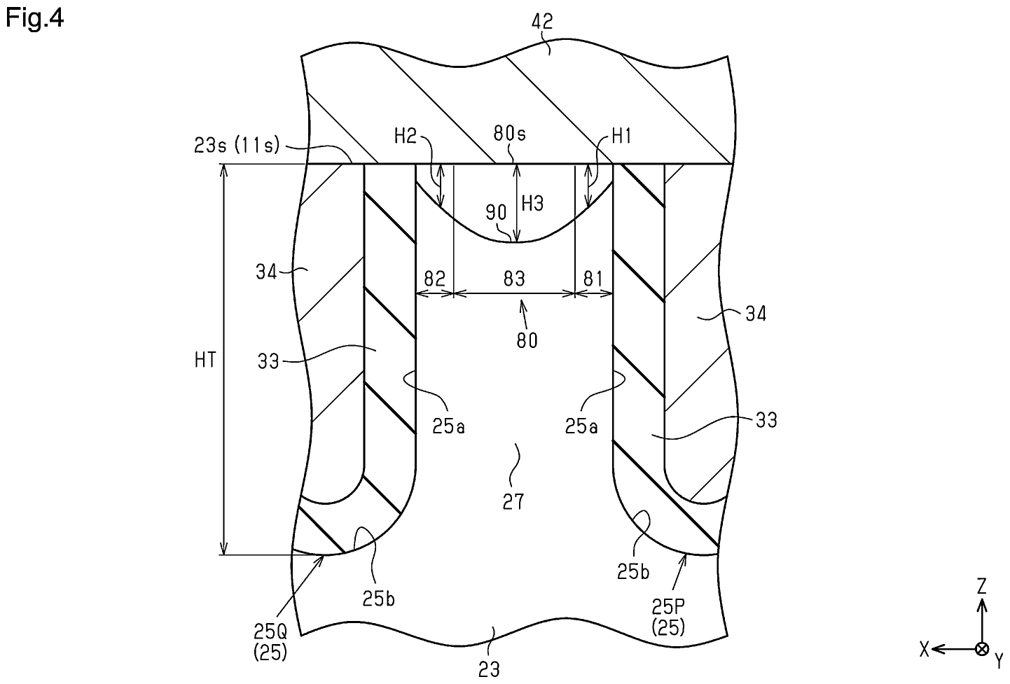

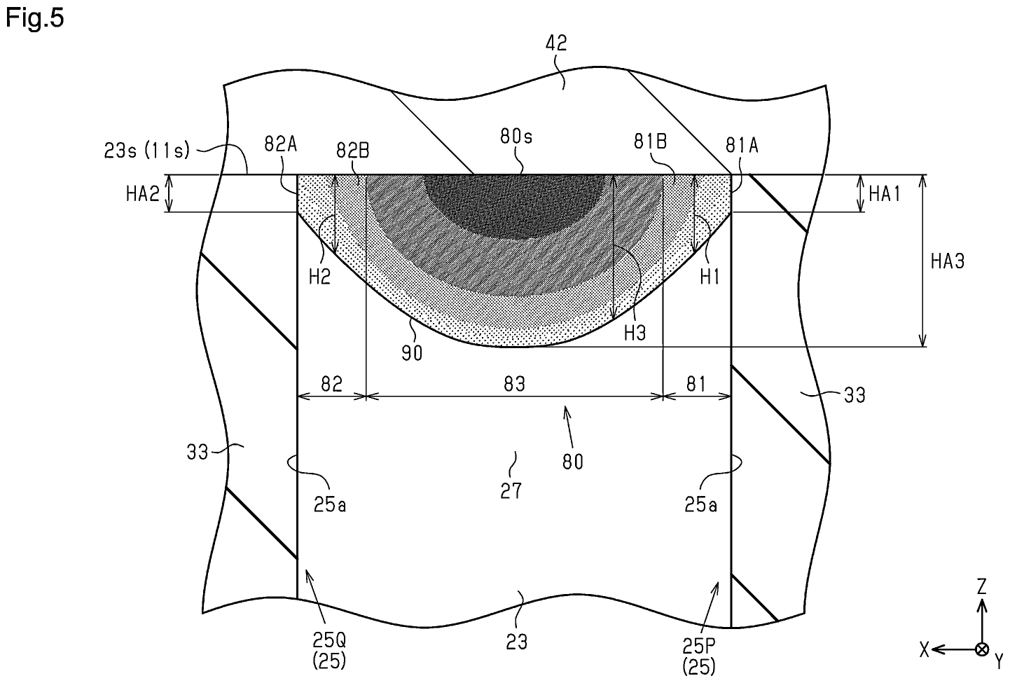

The configuration of two trenches 25 located adjacent to each other in the X-axis direction will now be described in detail with reference to FIGS. 3 to 5. FIG. 4 is an enlarged view showing the configuration of two of the trenches 25 shown in FIG. 3. FIG. 5 is an enlarged view showing the configuration of the front surface 23s of the drift layer 23 and its surroundings shown in FIG. 4. In FIG. 5, variations of the p-type impurity concentration are expressed by the density of dots. In FIG. 5, an increase in the density of dots indicates an increase in the p-type impurity concentration. In the description hereafter, for the sake of brevity, two trenches 25 located adjacent to each other in the X-axis direction are referred to as a “first trench 25P” and a “second trench 25Q.” A region of the drift layer 23 between the first trench 25P and the second trench 25Q is referred to as an “inter-trench region 27.”

### Shape of Well Region

The shape of a well region 80 will now be described.

As shown in FIG. 4, a p-type well region 80 is formed in the inter-trench region 27. The well region 80 is formed in the front surface 23s of the drift layer 23. The well region 80 is in contact with both the first trench 25P and the second trench 25Q. Thus, the well region 80 is formed in the entirety of the inter-trench region 27 in the X-axis direction. As shown in FIG. 3, the well region 80 is formed in the active region 51. In the present embodiment, the well region 80 is also formed in regions between the isolation trench 24 and each of the two trenches 25 located at opposite ends of the trenches 25 in the X-axis direction. However, the well regions 80 may be omitted from the regions between the isolation trench 24 and each of the two trenches 25 located at opposite ends of the trenches 25 in the X-axis direction.

The anode electrode 42 is in contact with each well region 80 in the active region 51. More specifically, the anode electrode 42 is in ohmic contact with the well region 80 in the active region 51.

As shown in FIG. 4, the well region 80 includes a first region 81 located adjacent to the first trench 25P, a second region 82 located adjacent to the second trench 25Q, and a third region 83 located between the first region 81 and the second region 82 in the X-axis direction. For the sake of convenience, the well region 80 is divided into three regions, namely, the first region 81, the second region 82, and the third region 83 in the X-axis direction.

In the present embodiment, the first region 81 and the second region 82 each have a smaller width-wise dimension than the third region 83. The first region 81 and the second region 82 are equal in width-wise dimension.

The first region 81 is arranged at a position separated from a central portion of the well region 80 in the X-axis direction toward the first trench 25P. The first region 81 has a thickness that decreases from the third region 83 toward the first trench 25P. In the present embodiment, the first region 81 is in contact with an upper end of the side wall 25a of the first trench 25P.

The second region 82 is arranged at a position separated from the central portion of the well region 80 in the X-axis direction toward the second trench 25Q. The second region 82 has a thickness that decreases from the third region 83 toward the second trench 25Q. In the present embodiment, the second region 82 is in contact with an upper end of the side wall 25a of the second trench 25Q.

The third region 83 includes the central portion of the well region 80. In other words, the third region 83 includes a central portion of the inter-trench region 27 in the X-axis direction. In the present embodiment, the third region 83 has a thickness that decreases from the central portion of the well region 80 toward the first region 81 and the second region 82.

As described above, an interface 90 between the well region 80 and the drift layer 23 is convex toward the semiconductor substrate 21 (refer to FIG. 3) as a distance from each of the first trench 25P and the second trench 25Q is increased. Thus, the third region 83 has a thickness-wise dimension H3 that is greater than a thickness-wise dimension H1 of the first region 81 and a thickness-wise dimension H2 of the second region 82. In other words, the thickness-wise dimension H1 of the first region 81 and the thickness-wise dimension H2 of the second region 82 are each smaller than the thickness-wise dimension H3 of the third region 83. The thickness-wise dimensions H1, H2, and H3 do not include a thickness-wise dimension of a boundary portion between the first region 81 and the third region 83 and a boundary portion between the second region 82 and the third region 83.

As shown in FIG. 5, the central portion of the well region 80 in the X-axis direction has a thickness-wise dimension HA3 having the maximum value of the thickness-wise dimension of the well region 80. The first region 81 includes a portion 81A in contact with the first trench 25P. The second region 82 includes a portion 82A in contact with the second trench 25Q. A thickness-wise dimension HA1 of the portion 81A or a thickness-wise dimension HA2 of the portion 82A is the minimum value of the thickness-wise dimension of the well region 80. The thickness-wise dimension HA1 refers to the minimum value of the thickness-wise dimension H1 of the first region 81. The thickness-wise dimension HA2 refers to the minimum value of the thickness-wise dimension H2 of the second region 82. The thickness-wise dimension of the well region 80 is defined by a distance between the front surface 23s of the drift layer 23 and the interface 90 in the Z-axis direction. Also, the thickness-wise dimension H1 of the first region 81, the thickness-wise dimension H2 of the second region 82, and the thickness-wise dimension H3 of the third region 83 may be defined in the same manner.

In the present embodiment, the maximum value of the thickness-wise dimension of the well region 80, that is, the thickness-wise dimension HA3 of the central portion of the well region 80, is less than a depth-wise dimension HT (refer to FIG. 4) of the trench 25. In an example, the thickness-wise dimension HA3 is less than or equal to ½ of the depth-wise dimension HT. The thickness-wise dimension HA3 may be less than or equal to ⅓ of the depth-wise dimension HT.

A ratio RH of the minimum value to the maximum value of the thickness-wise dimension of the well region 80 may be defined by a ratio of the thickness-wise dimension HA1 of the portion 81A of the first region 81 that is in contact with the first trench 25P to the thickness-wise dimension HA3 of the central portion of the well region 80 (RH=HA1/HA3). Also, the ratio RH may be defined by a ratio of the thickness-wise dimension HA2 of the portion 82A of the second region 82 that is in contact with the second trench 25Q to the thickness-wise dimension HA3 of the central portion of the well region 80 (RH=HA2/HA3). More specifically, the smaller one of the thickness-wise dimension HA1 and the thickness-wise dimension HA2 is used to set the ratio RH. In the present embodiment, the thickness-wise dimension HA1 is equal to the thickness-wise dimension HA2. Thus, any of the thickness-wise dimension HA1 and the thickness-wise dimension HA2 is used to set the ratio RH. In the semiconductor device 10, the ratio RH may be in a range of 0.1 to 0.3. The ratio RH may be changed in any manner.

The thickness-wise dimension HA1 may be in a range of 1/20 to 3/20 of the depth-wise dimension HT. The thickness-wise dimension HA2 may be in a range of 1/20 to 3/20 of the depth-wise dimension HT. The relationship of the thickness-wise dimensions HA1 and HA2 with the depth-wise dimension HT may be changed in any manner.

p-Type Impurity Concentration of Well Region

The p-type impurity concentration of the well region 80 will now be described.

As shown in FIG. 5, the well region 80 has a concentration gradient of the p-type impurity concentration in the X-axis direction and the Z-axis direction. In the description of the concentration gradient of the p-type impurity concentration of the well region 80, the p-type impurity concentrations of the first region 81, the second region 82, and the third region 83 are compared with each other at the same position in the Z-axis direction, unless otherwise specified.

Each of the first region 81 and the second region 82 is lower in p-type impurity concentration than the third region 83. In other words, each of the first region 81 and the second region 82 includes a region in which the p-type impurity concentration is lower than that of the third region 83. That is, the entirety of the third region 83 does not necessarily have to be higher in p-type impurity concentration than each of the first region 81 and the second region 82.

The first region 81 or the second region 82 is lowest in p-type impurity concentration in the well region 80. In other words, the first region 81 includes a region having the lowest p-type impurity concentration of the well region 80. In other words, the second region 82 includes a region having the lowest p-type impurity concentration of the well region 80.

The central portion of the third region 83 in the X-axis direction (the central portion of the well region 80 in the X-axis direction) has the highest p-type impurity concentration in the well region 80. In other words, the third region 83 includes a region having the highest p-type impurity concentration in the well region 80. As described above, in the present embodiment, the p-type impurity concentration of the well region 80 decreases from the third region 83 toward the first region 81 and the second region 82 in the X-axis direction.

The first region 81 includes a portion 81B located adjacent to the third region 83. In the first region 81, the p-type impurity concentration gradually decreases from the portion 81B toward the portion 81A, which is in contact with the first trench 25P. The p-type impurity concentration of the first region 81 decreases as the distance from a front surface 80s of the well region 80 (the front surface 23s of the drift layer 23) increases. Thus, the portion of the first region 81 that is located in the front surface 80s of the well region 80 and adjacent to the third region 83 has the highest p-type impurity concentration in the first region 81. From the portion of the first region having the highest p-type impurity concentration toward the first trench 25P, the p-type impurity concentration decreases as the distance from the head surface 80s of the well region 80 increases. Thus, the portion 81A of the first region 81, which is located adjacent to the first trench 25P, has the lowest p-type impurity concentration. Also, the interface 90 of the first region 81 between the well region 80 and the drift layer 23 has the lowest p-type impurity concentration. Therefore, in the present embodiment, the portion 81A of the first region 81, which is located adjacent to the first trench 25P, is equal in p-type impurity concentration to the interface 90 of the first region 81 between the well region 80 and the drift layer 23.

The second region 82 includes a portion 82B located adjacent to the third region 83. In the second region 82, the p-type impurity concentration gradually decreases from the portion 82B toward the portion 82A, which is in contact with the second trench 25Q. The p-type impurity concentration of the second region 82 decreases as the distance from the front surface 80s of the well region 80 (the front surface 23s of the drift layer 23) increases. Thus, the portion of the second region 82 that is located in the front surface 80s of the well region 80 and adjacent to the third region 83 has the highest p-type impurity concentration in the second region 82. From the portion of the second region 82 having the highest p-type impurity concentration toward the second trench 25Q, the p-type impurity concentration decreases as the distance from the front surface 80s of the well region 80 increases. Thus, the portion 82A of the second region 82, which is located adjacent to the second trench 25Q, has the lowest p-type impurity concentration. Also, the interface 90 of the second region 82 between the well region 80 and the drift layer 23 has the lowest p-type impurity concentration. Therefore, in the present embodiment, the portion 82A of the second region 82, which is located adjacent to the second trench 25Q, is equal in p-type impurity concentration to the interface 90 of the second region 82 between the well region 80 and the drift layer 23.

In the present embodiment, the portion 81A of the first region 81 that is located adjacent to the first trench 25P, the interface 90 of the first region 81 between the well region 80 and the drift layer 23, the portion 82A of the second region 82 that is located adjacent to the second trench 25Q, and the interface 90 of the second region 82 between the well region 80 and the drift layer 23 have the lowest p-type impurity concentration in the well region 80.

In the third region 83, the p-type impurity concentration gradually decreases from the central portion of the third region 83 in the X-axis direction toward the first region 81 and the second region 82. The p-type impurity concentration of the third region 83 decreases as the distance from the front surface 80s of the well region 80 (the front surface 23s of the drift layer 23) increases. Thus, the central portion of the third region 83 in the X-axis direction that is located in the front surface 80s of the well region 80 in the third region 83 has the highest p-type impurity concentration in the third region 83. From the portion having the highest p-type impurity concentration toward the first region 81 and the second region 82, the p-type impurity concentration decreases as the distance from the front surface 80s of the well region 80 increases. Thus, the central portion of the third region 83 in the X-axis direction that is located in the front surface 80s of the well region 80 in the third region 83 has the highest p-type impurity concentration in the well region 80. The interface 90 of the third region 83 between the well region 80 and the drift layer 23 has the lowest p-type impurity concentration in the third region 83.

As described above, in the present embodiment, the p-type impurity concentration of the well region 80 gradually decreases from the central portion of the well region 80 toward the end at the first trench 25P and the end at the second trench 25Q in the X-axis direction. The p-type impurity concentration of the well region 80 decreases as the distance from the front surface 80s of the well region 80 increases in the Z-axis direction.

In an example, the p-type impurity concentration of the portion 81A of the first region 81 that is in contact with the first trench 25P is less than or equal to 1/10 of the p-type impurity concentration of the central portion of the third region 83 in the X-axis direction. In an example, the p-type impurity concentration of the portion 82A of the second region 82 that is in contact with the second trench 25Q is less than or equal to 1/10 of the p-type impurity concentration of the central portion of the third region 83 in the X-axis direction. In an example, the p-type impurity concentration of the interface 90 between the well region 80 and the drift layer 23 is less than or equal to 1/10 of the p-type impurity concentration of the central portion of the third region 83 in the X-axis direction that is located in the front surface 80s of the well region 80.

The minimum value of the p-type impurity concentration of the first region 81 may be less than or equal to 1/10 of the maximum value of the p-type impurity concentration of the third region 83. The minimum value of the p-type impurity concentration of the second region 82 may be less than or equal to 1/10 of the maximum value of the p-type impurity concentration of the third region 83.

The average value of the p-type impurity concentration of the first region 81 may be less than or equal to 1/10 of the average value of the p-type impurity concentration of the third region 83. The average value of the p-type impurity concentration of the second region 82 may be less than or equal to 1/10 of the average value of the p-type impurity concentration of the third region 83.

The concentration gradient of the p-type impurity concentration of the well region 80 may be changed in any manner. In an example, the minimum value of the p-type impurity concentration of the third region 83, that is, the p-type impurity concentration of the interface 90 of the third region 83 may be less than each of the maximum value of the p-type impurity concentration of the first region 81 and the maximum value of the p-type impurity concentration of the second region 82. In the present embodiment, the minimum value of the p-type impurity concentration of the third region 83 is equal to the minimum value of the p-type impurity concentration of the first region 81. The minimum value of the p-type impurity concentration of the third region 83 is equal to the minimum value of the p-type impurity concentration of the second region 82. Therefore, the p-type impurity concentration of the interface 90 of the third region 83 is less than or equal to 1/10 of the p-type impurity concentration of the central portion of the third region 83 in the X-axis direction that is located in the front surface 80s of the well region 80.

The difference between the minimum value of the p-type impurity concentration of the interface 90 of the first region 81 and the maximum value of the p-type impurity concentration of the third region 83 at the same position as the interface 90 of the first region 81 in the Z-axis direction is less than the difference between the minimum value of the p-type impurity concentration of the first region 81 and the maximum value of the p-type impurity concentration of the third region 83 at the front surface 80s of the well region 80.

The difference between the minimum value of the p-type impurity concentration of the lower end of the second region 82 and the maximum value of the p-type impurity concentration of the third region 83 at the same position as the lower end of the second region 82 in the Z-axis direction is less than the difference between the minimum value of the p-type impurity concentration of the second region 82 and the maximum value of the p-type impurity concentration of the third region 83 at the front surface 80s of the well region 80.

In each of the first region 81 and the second region 82, the minimum value of the p-type impurity concentration is, for example, approximately 1×10¹⁵ cm⁻³. In each of the first region 81 and the second region 82, the p-type impurity concentration is, for example, in a range of 1×10¹⁵ cm⁻³ to 1×10¹⁷ cm⁻³. In the third region 83, the maximum value of the p-type impurity concentration is, for example, greater than or equal to 1×10¹⁶ cm⁻³. In the third region 83, the p-type impurity concentration is, for example, in a range of 1×10¹⁵ cm⁻³ to 1×10¹⁸ cm⁻³.

In the first region 81, the p-type impurity concentration does not have to have a concentration gradient in the Z-axis direction. In other words, in the first region 81, the p-type impurity concentration may be constant in the Z-axis direction. In the second region 82, the p-type impurity concentration does not have to have a concentration gradient in the Z-axis direction. In other words, in the second region 82, the p-type impurity concentration may be constant in the Z-axis direction. In the third region 83, the p-type impurity concentration does not have to have a concentration gradient in the Z-axis direction. In other words, in the third region 83, the p-type impurity concentration may be constant in the Z-axis direction. Hence, in the first region 81, the p-type impurity concentration of the interface 90 between the well region 80 and the drift layer 23 is equal to the p-type impurity concentration of the front surface 80s of the well region 80 at the same position in the X-axis direction. In the second region 82, the p-type impurity concentration of the interface 90 between the well region 80 and the drift layer 23 is equal to the p-type impurity concentration of the front surface 80s of the well region 80 at the same position in the X-axis direction. In the third region 83, the p-type impurity concentration of the interface 90 between the well region 80 and the drift layer 23 is equal to the p-type impurity concentration of the front surface 80s of the well region 80 at the same position in the X-axis direction.

As described above, when the p-type impurity concentration is constant in the Z-axis direction in the first region 81, the second region 82, and the third region 83, at least one of the portion 81A of the first region 81 that is located adjacent to the first trench 25P and the portion 82A of the second region 82 that is located adjacent to the second trench 25Q has the lowest p-type impurity concentration of the well region 80.

### Semiconductor Device Manufacturing Method

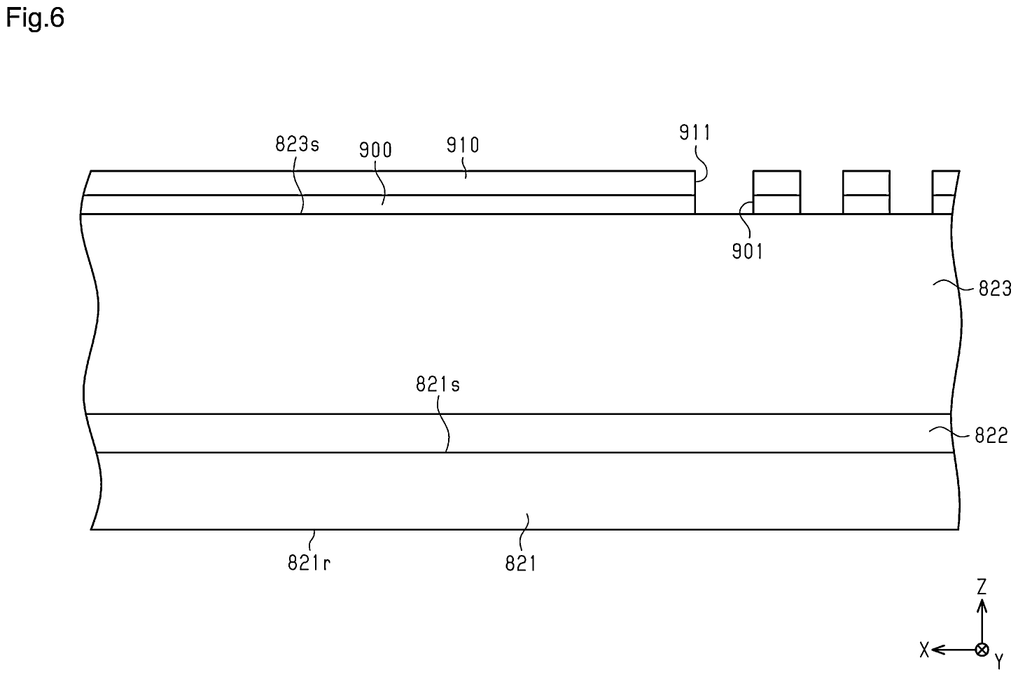

An example of a method for manufacturing the semiconductor device 10 will now be described with reference to FIGS. 6 to 18. FIGS. 6 to 18 are cross-sectional views showing a method for manufacturing the semiconductor device 10 including partially enlarged views of the active region 51 and the peripheral region 52.

As shown in FIG. 6, a semiconductor wafer 821 is prepared as the base of the semiconductor substrate 21. The semiconductor wafer 821 includes a wafer front surface 821s and a wafer back surface 821r opposite to the wafer front surface 821s. The semiconductor wafer 821 is, for example, a Si wafer. In the present embodiment, the semiconductor wafer 821 corresponds to a “semiconductor substrate,” the wafer front surface 821s corresponds to a “substrate front surface,” and the wafer back surface 821r corresponds to a “substrate back surface” in the method for manufacturing the semiconductor device.

A crystal structure of Si is grown from the wafer front surface 821s of the semiconductor wafer 821 through an epitaxial growth process. As a result, a buffer layer 822 and a drift layer 823 each having a predetermined n-type impurity concentration are formed in this order. In the present embodiment, the drift layer 823 corresponds to a “semiconductor layer” in the method for manufacturing the semiconductor device.

Subsequently, a mask 900 is formed on a front surface 823s of the drift layer 823. The mask 900 may be formed of a SiO₂ film. The mask 900 may be formed through at least one of chemical vapor deposition (CVD) and a thermal oxidation process. In the present embodiment, the mask 900 is formed through a thermal oxidation process.

Subsequently, a first resist mask 910 having a predetermined pattern is formed on the mask 900. The first resist mask 910 includes openings 911 corresponding to regions of the front surface 823s of the drift layer 823 in which the isolation trench 24 and the trenches 25 (refer to FIG. 3) are formed.

Etching is performed through the first resist mask 910 so that openings 901 are formed in portions of the mask 900 exposed from the openings 911. The openings 901 and 911 expose the regions of the front surface 823s of the drift layer 823 in which the isolation trench 24 and the trenches 25 are formed. After the openings 901 are formed in the mask 900, the first resist mask 910 is removed.

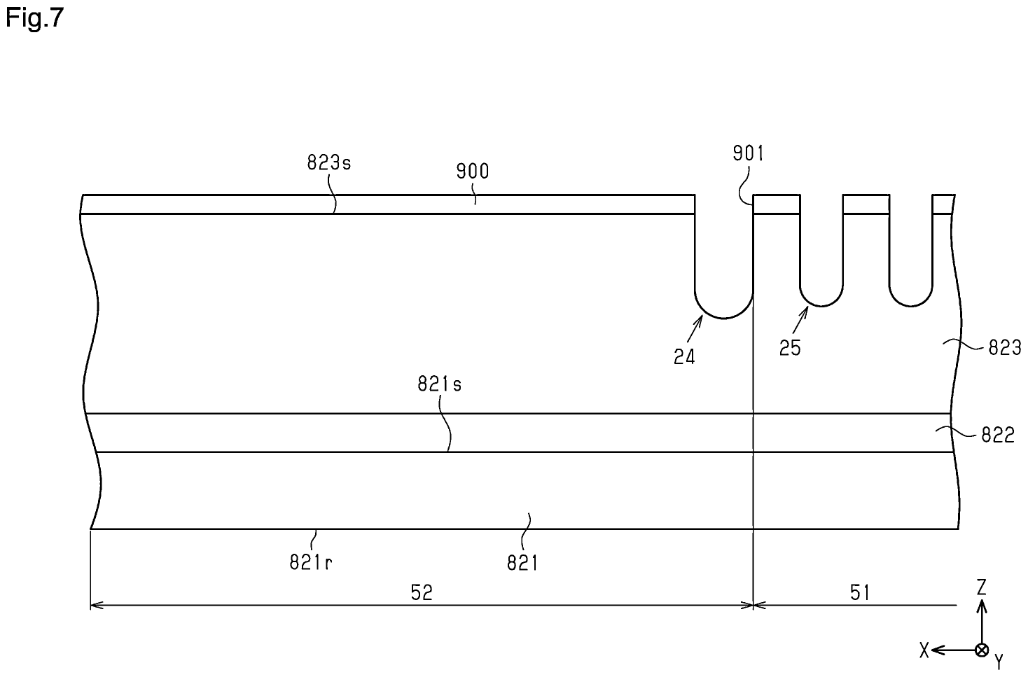

As shown in FIG. 7, etching is performed through the mask 900 to remove portions of the front surface 823s of the drift layer 823 in which the isolation trench 24 and the trenches 25 are formed. As a result, the isolation trench 24 and the trenches 25 are formed. The isolation trench 24 extends from the front surface 823s of the drift layer 823 in the Z-axis direction and has the form of a rectangular frame in plan view. Each trench 25 extends from the front surface 823s of the drift layer 823 in the Z-axis direction and the Y-axis direction. The trenches 25 are each in communication with the isolation trench 24. The trenches 25 are separated from each other in the X-axis direction. Of the trenches 25, two trenches 25 located adjacent to each other in the X-axis direction correspond to the first trench 25P and the second trench 25Q (refer to FIG. 5). In the description of the method for manufacturing the semiconductor device 10, unless otherwise specified, the simple term as “the trench 25” may refer to the first trench 25P and the second trench 25Q.

The isolation trench 24 separates the active region 51 and the peripheral region 52. The etching may be at least one of wet etching and dry etching. In the present embodiment, dry etching is used. Dry etching may be, for example, reactive ion etching (RIE). After the isolation trench 24 and the trenches 25 are formed, the mask 900 is removed.

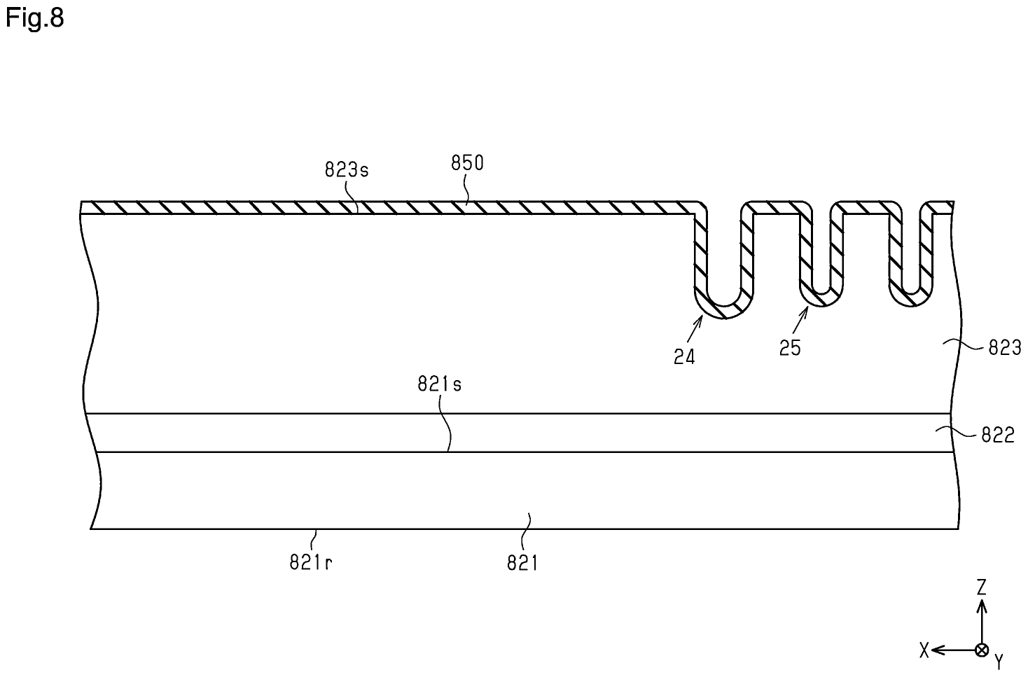

As shown in FIG. 8, at least one of CVD and a thermal oxidation process is performed to form a first base insulation film 850 on the front surface 823s of the drift layer 823, the walls of the isolation trench 24, and the walls of the trenches 25. In the present embodiment, the first base insulation film 850 is formed through a thermal oxidation process. The first base insulation film 850 is a field oxide film. The first base insulation film 850 is formed by a SiO₂ film. The first base insulation film 850 serves as the base of each of the isolation insulation film 31, the insulation layer 33 of the trenches 25, and the first insulation film 61 (refer to FIG. 3). The first base insulation film 850 grows by absorbing the n-type impurity from the vicinity of the drift layer 823. Thus, the first base insulation film 850 includes the n-type impurity of the drift layer 823. In the present embodiment, the first base insulation film 850 corresponds to an “insulation layer” in the method for manufacturing the semiconductor device.

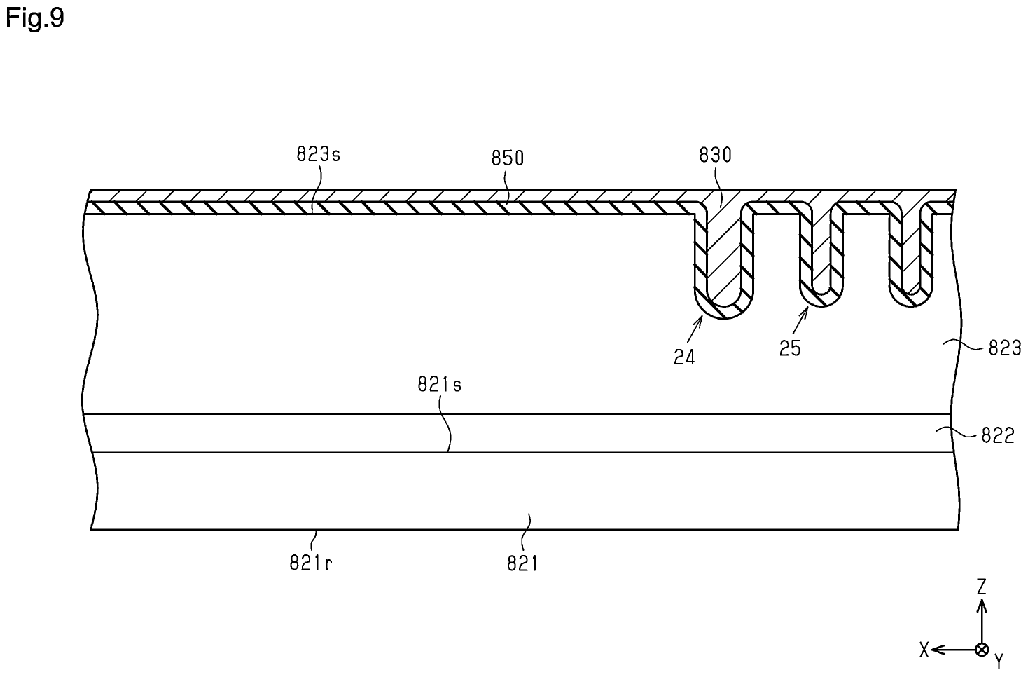

As shown in FIG. 9, CVD is performed to form the first base electrode film 830 on the first base insulation film 850. The first base electrode film 830 serves as the base of each of the isolation electrode 32 and the embedded electrode 34 (refer to FIG. 3). The first base electrode film 830 fills a first recess space defined by the first base insulation film 850 in the isolation trench 24 and a second recess space defined by the first base insulation film 850 in the trench 25. The first base electrode film 830 is also formed on the entirety of the front surface 823s of the drift layer 823. The first base electrode film 830 is formed from, for example, a conductive polysilicon.

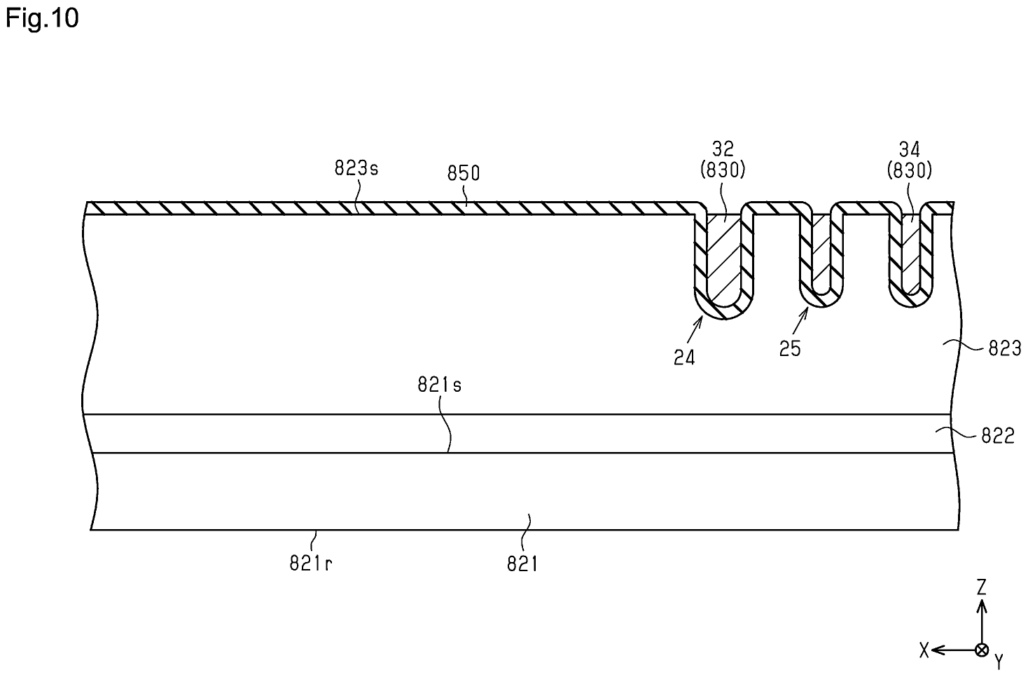

As shown in FIG. 10, etching is performed to remove the portions of the first base electrode film 830 excluding the portions that fill the first recess space and the second recess space. This forms the isolation electrode 32 and the embedded electrode 34. The etching is, for example, at least one of wet etching and dry etching. In the present embodiment, the embedded electrode 34 corresponds to a “third electrode” in the method for manufacturing the semiconductor device.

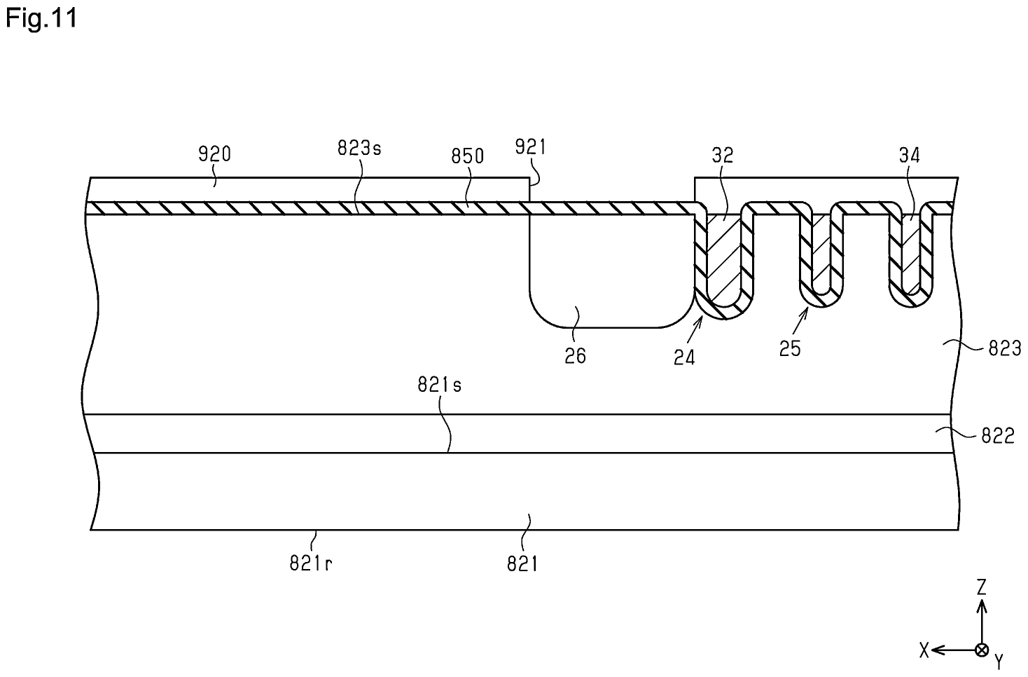

As shown in FIG. 11, a second resist mask 920 having a predetermined pattern is formed on the first base insulation film 850. The second resist mask 920 includes an opening 921 that exposes the region of the front surface 823s of the drift layer 823 in which the peripheral well region 26 is formed.

An ion implantation process is performed through the second resist mask 920 to implant a p-type impurity into the front surface 823s of the drift layer 823. The p-type impurity is implanted into a surface portion of the drift layer 823 through the first base insulation film 850. Then, a drive-in process is performed so that the p-type impurity implanted into the surface portion of the drift layer 823 diffuses in the width-wise direction (X-axis direction) and the depth-wise direction (Z-axis direction) of the drift layer 823. The steps described above form the peripheral well region 26. After the peripheral well region 26 is formed, the second resist mask 920 is removed.

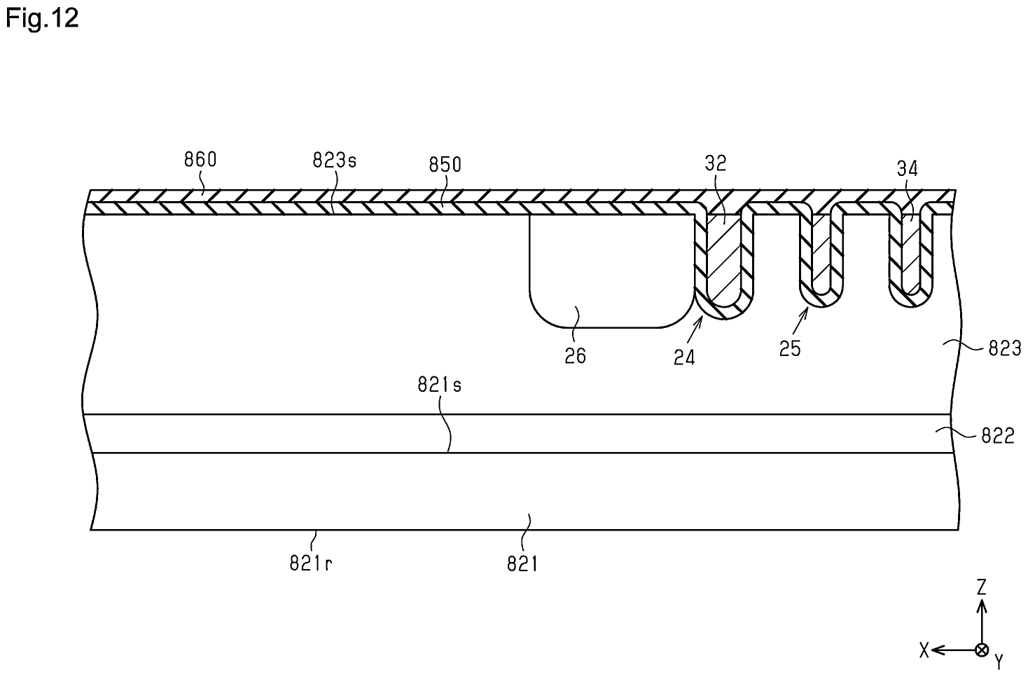

As shown in FIG. 12, CVD is performed to form a second base insulation film 860 on the first base insulation film 850, the isolation electrode 32, and the embedded electrode 34. The second base insulation film 860 serves as the base of the second insulation film 62. The second base insulation film 860 and the first base insulation film 850 are formed from different insulation materials. More specifically, the second base insulation film 860 is formed of a SiO₂ film that differs in property from the first base insulation film 850. The second base insulation film 860 includes, for example, at least one of a PSG film and a USG film.

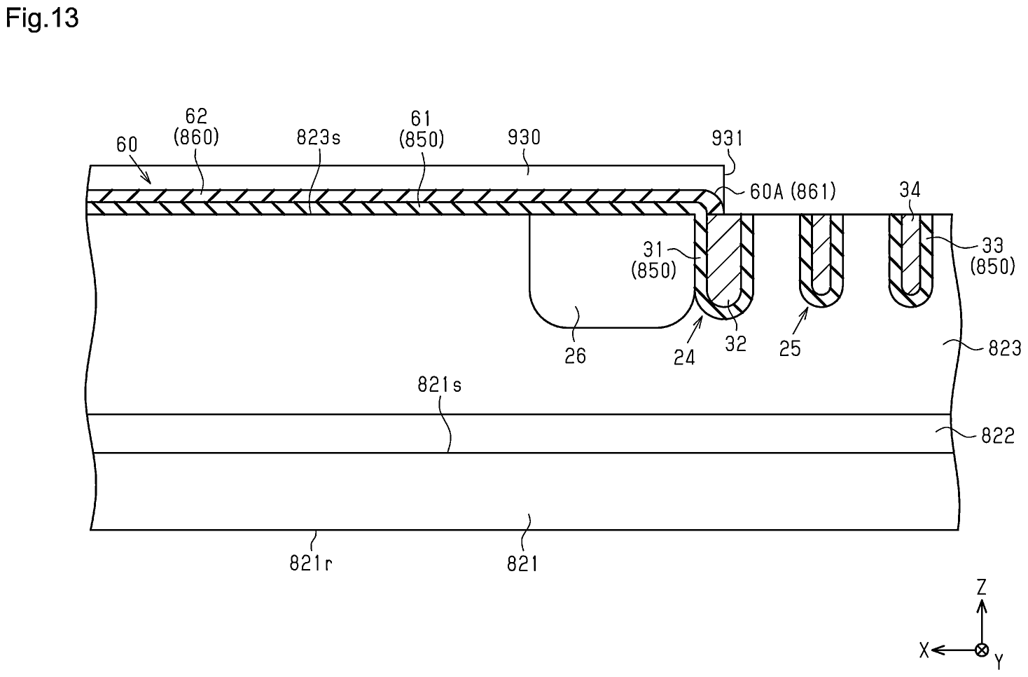

As shown in FIG. 13, a third resist mask 930 having a predetermined pattern is formed on the second base insulation film 860. The third resist mask 930 includes an opening 931 that exposes the region of the second base insulation film 860 in which the through hole 60A is formed in the surface insulation layer 60. Etching is performed through the third resist mask 930 to remove the portion of the second base insulation film 860 exposed by the opening 931. The etching is at least one of wet etching and dry etching. In the present embodiment, dry etching (e.g., RIE) is used. As a result, a through hole 861 is formed in the second base insulation film 860.

Subsequently, etching is performed through the third resist mask 930 to remove the portion of the first base insulation film 850 exposed by the opening 931 and the through hole 861. The etching is at least one of wet etching and dry etching. In the present embodiment, dry etching (e.g., RIE) is used. As a result, the first base insulation film 850 is separated into the isolation insulation film 31, the insulation layer 33, and the first insulation film 61. The second base insulation film 860 serves as the second insulation film 62. Thus, the surface insulation layer 60 having a stacking structure of the first insulation film 61 and the second insulation film 62 is formed on the front surface 823s of the drift layer 823. After the first base insulation film 850 and the second base insulation film 860 are patterned, the third resist mask 930 is removed.

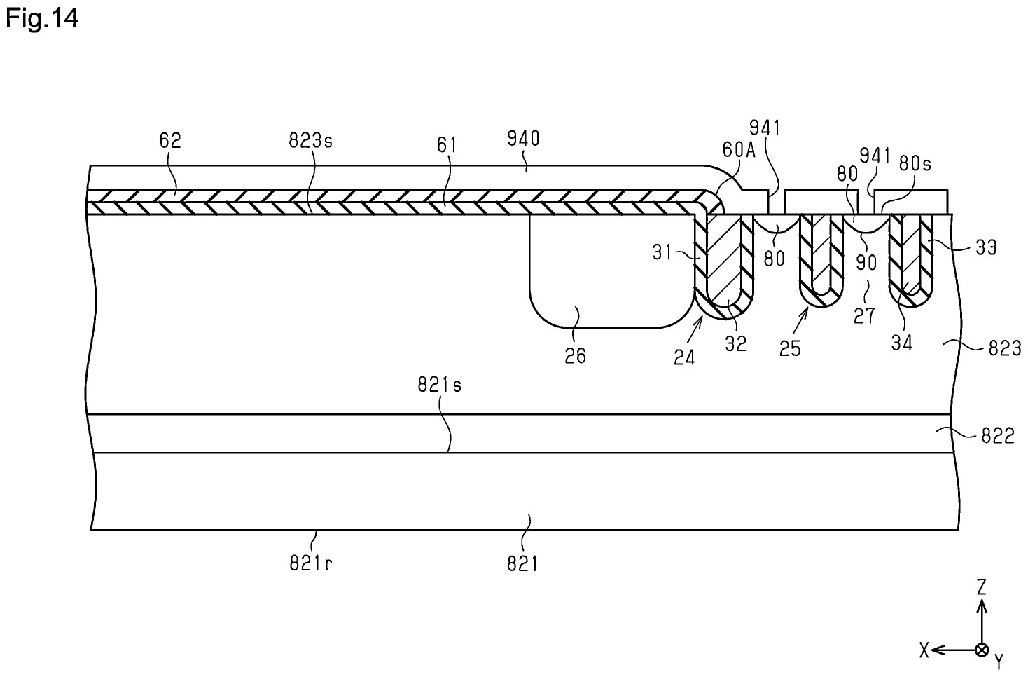

As shown in FIG. 14, a fourth resist mask 940 having a predetermined pattern is formed on the surface insulation layer 60. The fourth resist mask 940 includes openings 941 that expose a central portion of the inter-trench region 27 in the X-axis direction in the front surface 823s of the drift layer 823. The openings 941 of the fourth resist mask 940 are formed for each inter-trench region 27. In plan view, the openings 941 are smaller in width than the inter-trench region 27. The width of the inter-trench region 27 is defined by the dimension of the inter-trench region 27 in the X-axis direction, that is, the distance between two trenches 25 located adjacent to each other in the X-axis direction. The width of the opening 941 is defined by the dimension of the opening 941 in the X-axis direction. In the present embodiment, the fourth resist mask 940 corresponds to a “mask.”

The fourth resist mask 940 covers two ends of the inter-trench region 27 in the X-axis direction corresponding to the first region 81 and the second region 82 (refer to FIG. 5) of the well region 80. On the other hand, the fourth resist mask 940 exposes the central portion of the inter-trench region 27 in the X-axis direction through the opening 941 corresponding to the third region 83 (refer to FIG. 5) of the well region 80.

The ratio of the width of the opening 941 to the width of the inter-trench region 27 is, for example, less than or equal to 0.8. The ratio of the width of the opening 941 to the width of the inter-trench region 27 is, for example, less than or equal to 0.5. The ratio of the width of the opening 941 to the width of the inter-trench region 27 is, for example, in a range of 0.1 to 0.5. In the present embodiment, the ratio of the width of the opening 941 to the width of the inter-trench region 27 is 0.43. In this case, the width of the opening 941 is 0.3 μm. An increase in the ratio increases the thickness-wise dimension of the well region 80 and decreases the curvature of the interface 90 between the well region 80 and the drift layer 23.

Subsequently, an ion implantation process is performed through the fourth resist mask 940 to implant a p-type impurity into the front surface 823s of the drift layer 823. More specifically, the p-type impurity is implanted into the inter-trench region 27 through the openings 941. The p-type impurity is implanted into a surface portion of the drift layer 823. Then, a drive-in process is performed so that the p-type impurity implanted into the surface portion of the drift layer 823 diffuses in the width-wise direction (X-axis direction) and the depth-wise direction (Z-axis direction) of the drift layer 823. The steps described above form the well region 80. After the well region 80 is formed, the fourth resist mask 940 is removed. The specific configuration and the concentration gradient of the p-type impurity concentration of the well region 80 are the same as those of the well region 80 shown in FIGS. 4 and 5.

In the present embodiment, the number of times of performing the ion implantation process to implant the p-type impurity through the fourth resist mask 940 is, for example, one. The number of times of performing the ion implantation process to implant the p-type impurity into the fourth resist mask 940 may be, for example, multiple times. As the number of times of implanting the p-type impurity increases, the thickness-wise dimension of the well region 80 increases. In addition, the curvature of the interface 90 between the well region 80 and the drift layer 823 increases.

The ratio of the width of the opening 941 to the width of the inter-trench region 27 and the number of times of implantations may be changed in accordance with, for example, the shape of the interface 90 between the well region 80 and the drift layer 23 and the designed values of the thickness-wise dimension HA1 of the portion 81A of the first region 81 that is in contact with the first trench 25P and the thickness-wise dimension HA2 of the portion 82A of the second region 82 that is in contact with the second trench 25Q in the well region 80.

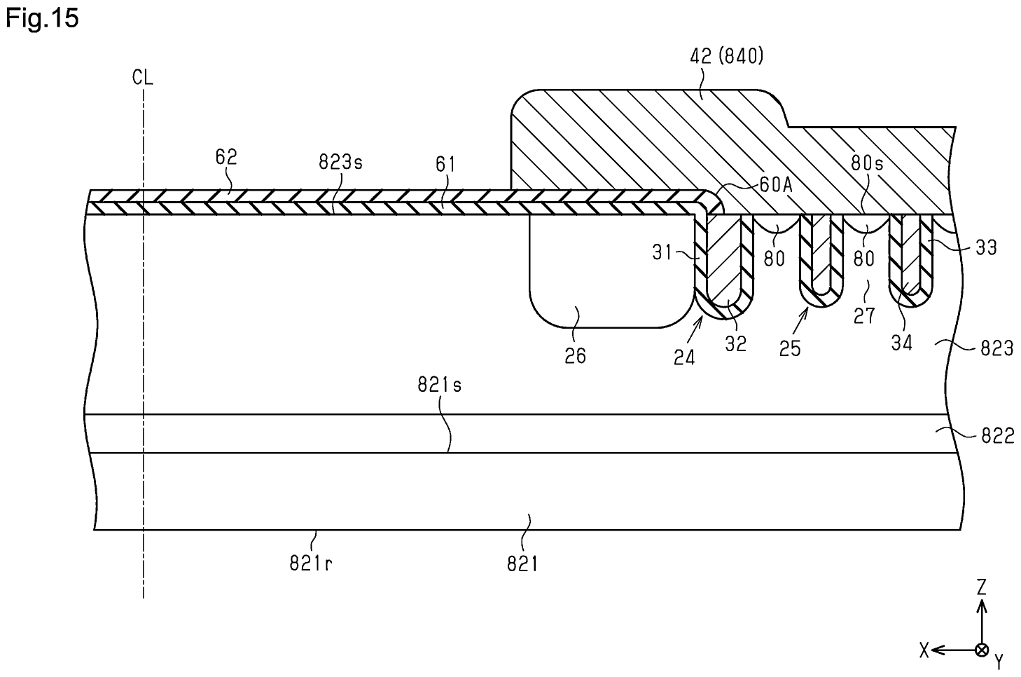

As shown in FIG. 15, CVD is performed to form a second base electrode film 840 on the front surface 80s of the well region 80, the isolation electrode 32, the embedded electrode 34, and the surface insulation layer 60. The second base electrode film 840 is in ohmic contact with each of the front surface 80s of the well region 80, the isolation electrode 32, and the embedded electrode 34. Thus, the second base electrode film 840 is electrically connected to the isolation electrode 32 and the embedded electrode 34. The second base electrode film 840 is insulated from the peripheral well region 26. In the present embodiment, the second base electrode film 840 corresponds to a “first electrode” in the method for manufacturing the semiconductor device.

The second base electrode film 840 has a stacking structure formed of the first electrode film, the second electrode film, and the third electrode film.

The first electrode film is formed to be in contact with the front surface 80s of the well region 80, the isolation electrode 32, the embedded electrode 34, and the surface insulation layer 60. In the present embodiment, the first electrode film is formed from a material including, for example, Ti. The second electrode film is formed on the first electrode film. In the present embodiment, the second electrode film is formed from a material including, for example, TiN. The third electrode film is formed on the second electrode film. In the present embodiment, the third electrode film is formed from a material including Al.

Each of the first electrode film, the second electrode film, and the third electrode film may be formed through, for example, at least one of sputtering, vapor deposition, and plating. In the present embodiment, the first electrode film, the second electrode film, and the third electrode film are each formed through sputtering.

Subsequently, although not shown, a sixth resist mask is formed on the second base electrode film 840. The sixth resist mask does not cover an outer peripheral portion of the second base electrode film 840. Etching is performed through the sixth resist mask to remove the outer peripheral portion of the second base electrode film 840. This forms the anode electrode 42.

Although not shown, the method for manufacturing the semiconductor device 10 further includes forming the surface protection layer 70, forming the cathode electrode 41, and singulating.

Forming the surface protection layer 70 is performed after the second base electrode film 840 is formed. In an example, CVD is performed to form the surface protection layer 70 on the surface insulation layer 60 and the second base electrode film 840.

The forming the cathode electrode 41 includes forming the cathode electrode 41 on the wafer back surface 821r of the semiconductor wafer 821. The cathode electrode 41 is in ohmic contact with the wafer back surface 821r of the semiconductor wafer 821. In the present embodiment, the cathode electrode 41 corresponds to a “second electrode” in the method for manufacturing the semiconductor device.

The singulating is performed after the surface protection layer 70 is formed. In an example, a dicing blade is used to cut the surface protection layer 70, the drift layer 823, the buffer layer 822, and the cathode electrode 41 along a cutting line CL indicated by the single dashed line shown in FIG. 15. The steps described above manufacture the semiconductor device 10.

### Operation

The operation of the present embodiment will now be described.

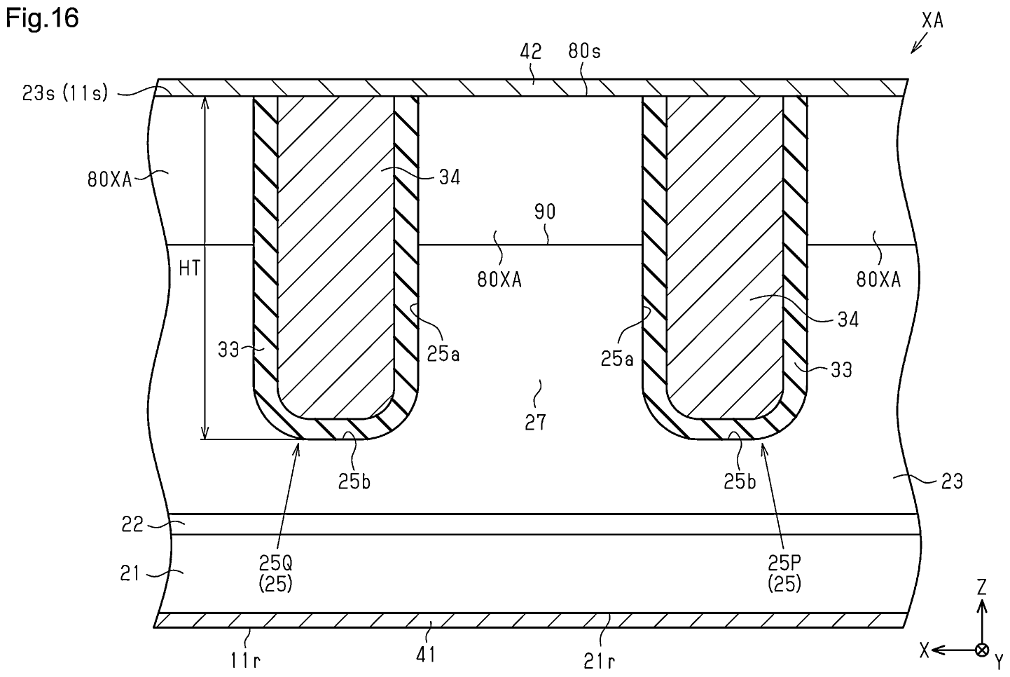

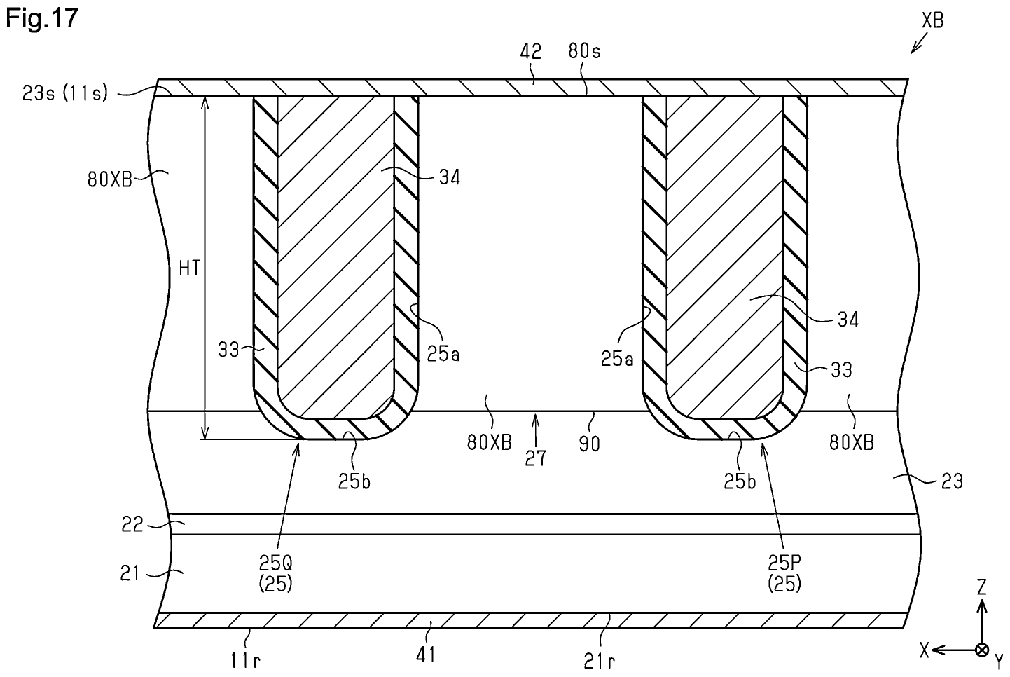

FIG. 16 is a cross-sectional view schematically showing the configuration of a semiconductor device XA in a first comparative example. FIG. 17 is a cross-sectional view schematically showing the configuration of a semiconductor device XB in a second comparative example. The semiconductor device XA of the first comparative example and the semiconductor device XB of the second comparative example differ from the semiconductor device 10 of the present embodiment in the structure of a well region.

As shown in FIG. 16, the semiconductor device XA of the first comparative example includes a well region 80XA having a constant thickness-wise dimension entirely in the X-axis direction. In addition, the p-type impurity concentration of the well region 80XA is constant in the entire well region 80XA. The thickness-wise dimension of the well region 80XA is approximately ½ of the depth-wise dimension HT of the trench 25.

As shown in FIG. 17, the semiconductor device XB of the second comparative example includes a well region 80XB having a constant thickness-wise dimension entirely in the X-axis direction. In addition, the p-type impurity concentration of the well region 80XB is constant in the entire well region 80XB. The thickness-wise dimension of the well region 80XB is approximately 9/10 of the depth-wise dimension HT of the trench 25.

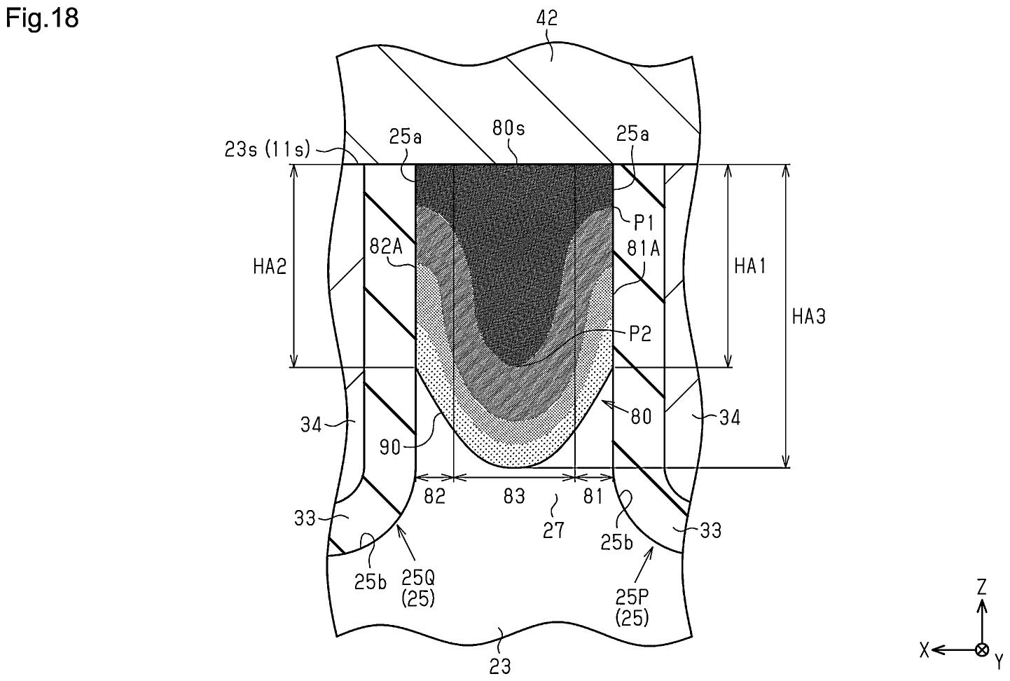

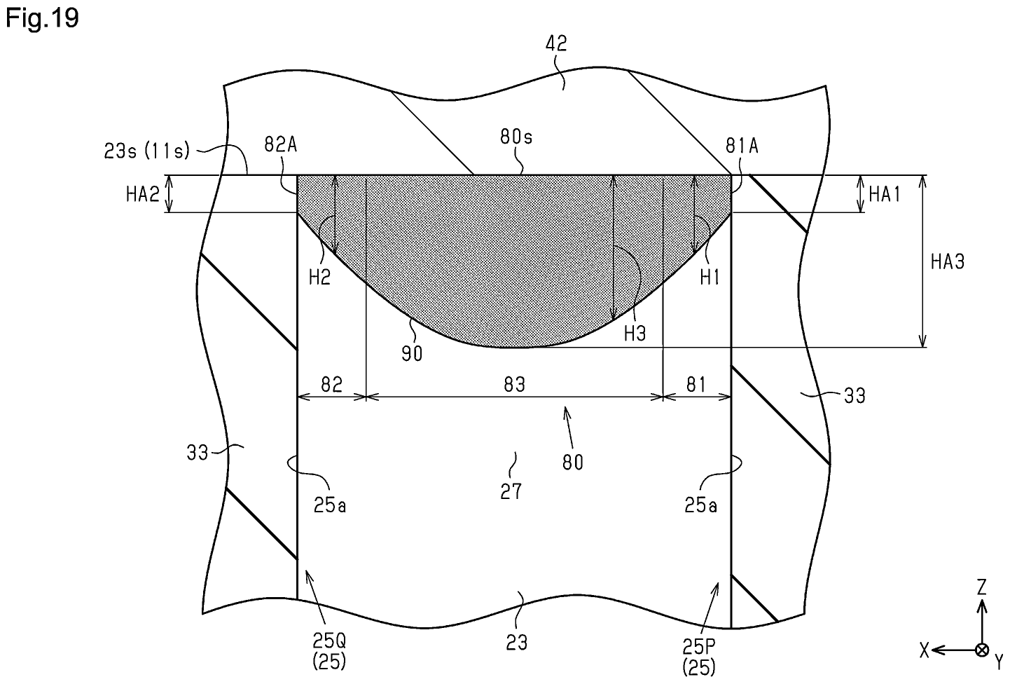

The semiconductor device 10 of the present embodiment is referred to as a first embodiment (for example, refer to FIG. 5). A semiconductor device 10 shown in FIG. 18 is referred to as a second embodiment. FIG. 18 is a cross-sectional view schematically showing the semiconductor device 10 of the second embodiment. FIG. 19 is a cross-sectional view schematically showing a third embodiment of a semiconductor device 10.

In the semiconductor device 10 of the second embodiment, the maximum value of the thickness-wise dimension of the well region 80 is greater than or equal to ½ of the depth-wise dimension HT of the trench 25. More specifically, the thickness-wise dimension HA3 of the central portion of the third region 83 in the X-axis direction is greater than the thickness-wise dimension HA3 of the first embodiment. The first region 81 has a thickness that decreases from the third region 83 toward the first trench 25P. The thickness-wise dimension HA1 of the portion 81A of the first region 81 that is in contact with the first trench 25P is greater than the thickness-wise dimension HA1 of the first embodiment. The second region 82 has a thickness that decreases from the third region 83 toward the second trench 25Q. The thickness-wise dimension HA2 of the portion 82A of the second region 82 that is in contact with the second trench 25Q is greater than the thickness-wise dimension HA2 of the first embodiment. The third region 83 has a thickness that decreases from a central portion of the third region 83 in the X-axis direction toward the first region 81 and the second region 82. The curvature of the interface 90 between the well region 80 and the drift layer 23 is greater than the curvature of the interface 90 between the well region 80 and the drift layer 23 in the first embodiment.

In the well region 80 of the second embodiment, the first to third regions 81 to 83 have the same p-type impurity concentration in the front surface 80s of the well region 80. In the illustrated example, the p-type impurity concentration is constant in a region between the front surface 80s of the well region 80 and a position P1 separated from the front surface 80s. The p-type impurity concentration of the region described above has the maximum value of the p-type impurity concentration of the well region 80.

The p-type impurity concentration of the first region 81 and the p-type impurity concentration of the second region 82 decrease as the distance from the front surface 80s of the well region 80 increases in a region beyond the position P1 from the front surface 80s. In the region beyond the position P1 from the front surface 80s of the well region 80, the p-type impurity concentration of the first region 81 and the p-type impurity concentration of the second region 82 gradually decrease as the distance from the front surface 80s of the well region 80 increases.

In the region beyond the position P1 from the front surface 80s of the well region 80, the p-type impurity concentration of the first region 81 and the p-type impurity concentration of the second region 82 are each lower than the p-type impurity concentration of the third region 83. At a position P2 separated farther than the position P1 from the front surface 80s of the well region 80, the p-type impurity concentration of the portion 81A of the first region 81 located adjacent to the first trench 25P or the p-type impurity concentration of the portion 82A of the second region 82 located adjacent to the second trench 25Q has the minimum value of the p-type impurity concentration of the well region 80. In the central portion of the third region 83 in the X-axis direction, the p-type impurity concentration is constant from the front surface 80s of the well region 80 to the position P2. The p-type impurity concentration described above is the maximum value of the p-type impurity concentration of the well region 80. In the semiconductor device 10 of the second embodiment, the well region 80 is formed by, for example, setting the width of the opening 941 (refer to FIG. 14) of the fourth resist mask 940 to 0.3 μm and performing ion implantation multiple times (e.g., three times). In this case, the ratio of the width of the opening 941 to the width of the inter-trench region 27 is approximately 0.43.

As shown in FIG. 19, in the semiconductor device 10 of the third embodiment, the p-type impurity concentration is constant in the entire well region 80. That is, in the well region 80, the p-type impurity concentration does not have a concentration gradient. The well region 80 of the third embodiment is identical in shape to the well region 80 of the first embodiment.

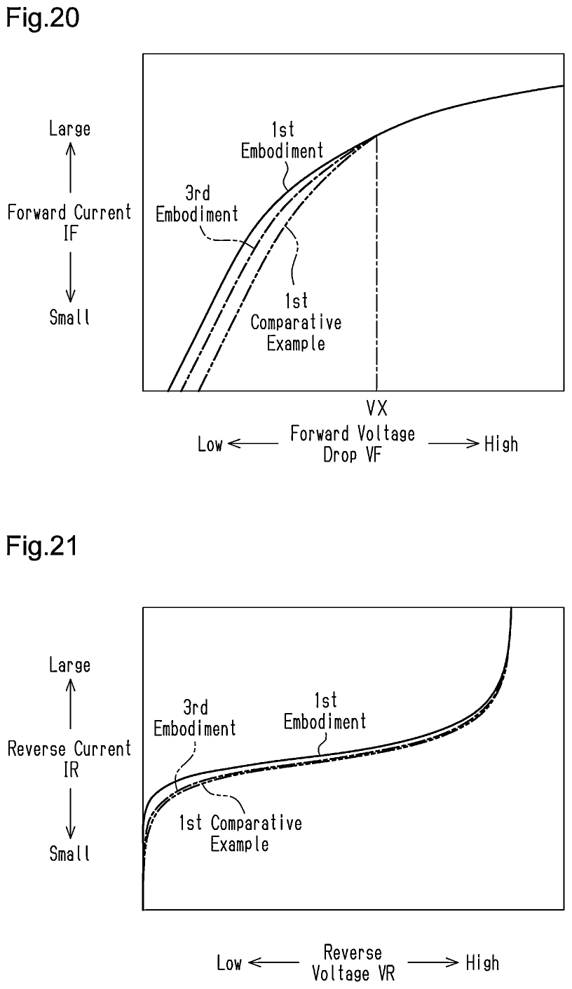

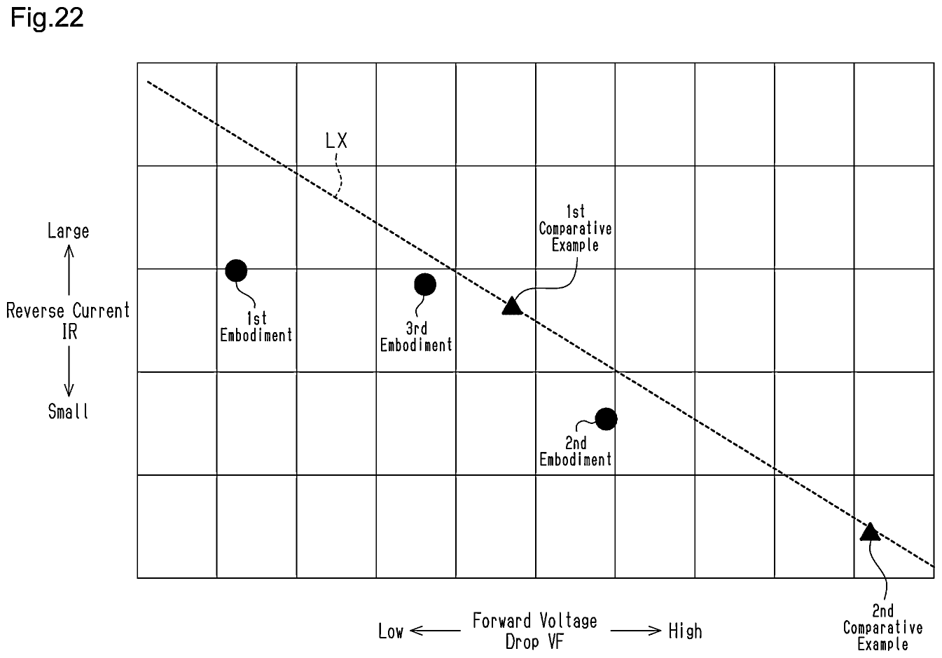

The electrical characteristics of the embodiments and comparative examples described above will be described with reference to FIGS. 20 to 22. FIG. 20 is a graph showing the relationship between forward voltage drop VF and forward current IF in the first embodiment, the third embodiment, and the first comparative example. FIG. 21 is a graph showing the relationship between reverse voltage VR and reverse current IR in the first embodiment, the third embodiment, and the first comparative example. FIG. 22 is a graph showing the relationship between the forward voltage drop VF when a predetermined forward current IF is applied and the reverse current IR when a predetermined reverse voltage VR is applied in the embodiments and comparative examples described above.

As shown in FIG. 20, when the forward voltage drop VF is less than or equal to a predetermined voltage VX and the forward current IF has the same value, in the semiconductor devices 10 of the first embodiment and the second embodiment, the forward voltage drop VF is smaller than in the semiconductor device XA of the first comparative example. When the forward voltage drop VF is less than or equal to the predetermined voltage VX and the forward current IF has the same value, in the semiconductor device 10 of the first embodiment, the forward voltage drop VF is smaller than in the semiconductor device 10 of the third embodiment. When the forward voltage drop VF is greater than the predetermined voltage VX, the relationship of the forward voltage drop VF with the forward current IF is the same among the semiconductor devices 10 of the first embodiment and the second embodiment and the semiconductor device XA of the first comparative example.

In the first embodiment and the second embodiment, the thickness-wise dimension HA1 of the portion 81A of the first region 81 that is in contact with the first trench 25P and the thickness-wise dimension HA2 of the portion 82A of the second region 82 that is in contact with the second trench 25Q in the well region 80 are each smaller than the thickness-wise dimension of the well region 80XA of the first comparative example. Thus, the electric field intensity is increased in the inter-trench region 27 in the vicinity of the insulation layer 33 of the first trench 25P and the second trench 25Q. This increases a channel current component, which may cause the forward voltage drop VF to decrease.

In the first embodiment, the p-type impurity concentration of each of the first region 81 and the second region 82 is lower than the p-type impurity concentration of the third region 83. Hence, when a forward bias is applied to the semiconductor device 10, an inversion layer is readily formed in the inter-trench region 27 in the vicinity of the insulation layer 33 of the first trench 25P and the second trench 25Q as compared to the second embodiment. As a result, the current density is increased in the inversion layer. This may cause the forward voltage drop VF to decrease.

As shown in FIG. 21, the relationship of the reverse voltage VR and the reverse current IR is generally the same between the semiconductor device 10 of the third embodiment and the semiconductor device XA of the first comparative example. The semiconductor device 10 of the first embodiment allows the reverse current IR to flow slightly more readily than the semiconductor device 10 of the third embodiment and the semiconductor device XA of the first comparative example. More specifically, the difference in the reverse current IR between the first comparative example, the first embodiment, and the third embodiment is in the order of 1/10000 to 1/1000. Therefore, the readiness of the reverse current IR flowing through the first comparative example, the first embodiment, and the third embodiment is almost the same.

As shown in FIG. 22, an approximate line LX is set from the semiconductor device XA of the first comparative example and the semiconductor device XB of the second comparative example. The approximate line LX shows the relationship between the forward voltage drop VF corresponding to application of the predetermined forward current IF and the reverse current IR corresponding to application of the predetermined reverse voltage VR when the well regions 80XA and 80XB do not have a concentration gradient of the p-type impurity concentration as in the first comparative example and the second comparative example. When the reverse current IR is less than the approximate line LX or the forward voltage drop VF is smaller than the approximate line LX, the electrical characteristics are considered satisfactory.

In the semiconductor device 10 of the second embodiment and the semiconductor device XB of the second comparative example, the reverse current IR is smaller than in the semiconductor device 10 of the first embodiment and the semiconductor device XA of the first comparative example.

As in the well region 80 of the second embodiment and the well region 80XB of the second comparative example, the thickness-wise dimension is increased by performing ion implantation multiple times. Thus, when reverse bias is applied to the semiconductor device 10, the depletion layer widely expands. This may cause the reverse current IR to decrease.

In the semiconductor device 10 of the second embodiment and the semiconductor device XB of the second comparative example, the forward voltage drop VF is high as compared to the semiconductor device 10 of the first embodiment and the semiconductor device XA of the first comparative example. Thus, when the well region 80 (80XA, 80XB) is large, the reverse current IR is decreased. However, the forward voltage drop VF is increased.

In the second embodiment of the well region 80, the thickness-wise dimension HA1 of the portion 81A of the first region 81 that is in contact with the first trench 25P and the thickness-wise dimension HA2 of the portion 82A of the second region 82 that is in contact with the second trench 25Q are each smaller than the thickness-wise dimension of the well region 80XA of the first comparative example. In the well region 80 of the second embodiment, each of the first region 81 and the second region 82 is lower in p-type impurity concentration than the third region 83. As described above, this may cause the forward voltage drop VF to decrease as compared to the second comparative example. In the semiconductor device 10 of the second embodiment, the reverse current IR and the forward voltage drop VF are smaller than the approximate line LX.

In the semiconductor device 10 of the first embodiment, the forward voltage drop VF is decreased as compared to the semiconductor device XA of the first comparative example and the semiconductor device XB of the second comparative example. In the semiconductor device 10 of the first embodiment, the forward voltage drop VF is lower than the semiconductor device 10 of the second embodiment. In the semiconductor device 10 of the first embodiment, the reverse current IR is larger than each of the semiconductor device XA of the first comparative example and the semiconductor device XB of the second comparative example. However, in the semiconductor device 10 of the first embodiment, the forward voltage drop VF is lowered at a large degree. As shown in FIG. 22, in the semiconductor device 10 of the first embodiment, the reverse current IR is lower than the approximate line LX, and the forward voltage drop VF is smaller than the approximate line LX.

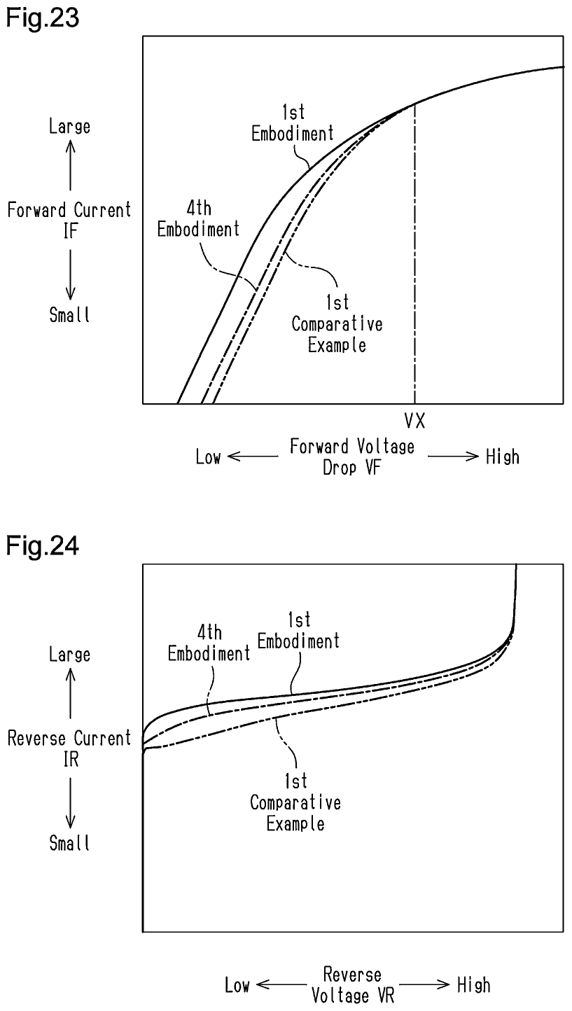

Electrical characteristics of semiconductor devices that differ in the ratio of the width of the opening 941 (refer to FIG. 14) of the fourth resist mask 940 to the width of the inter-trench region 27 will now be described with reference to FIGS. 23 and 24. FIG. 23 is a graph showing the relationship between forward voltage drop VF and forward current IF in the first embodiment, the fourth embodiment, and the first comparative example. FIG. 24 is a graph showing the relationship between reverse voltage VR and reverse current IR in the first embodiment, the fourth embodiment, and the first comparative example.

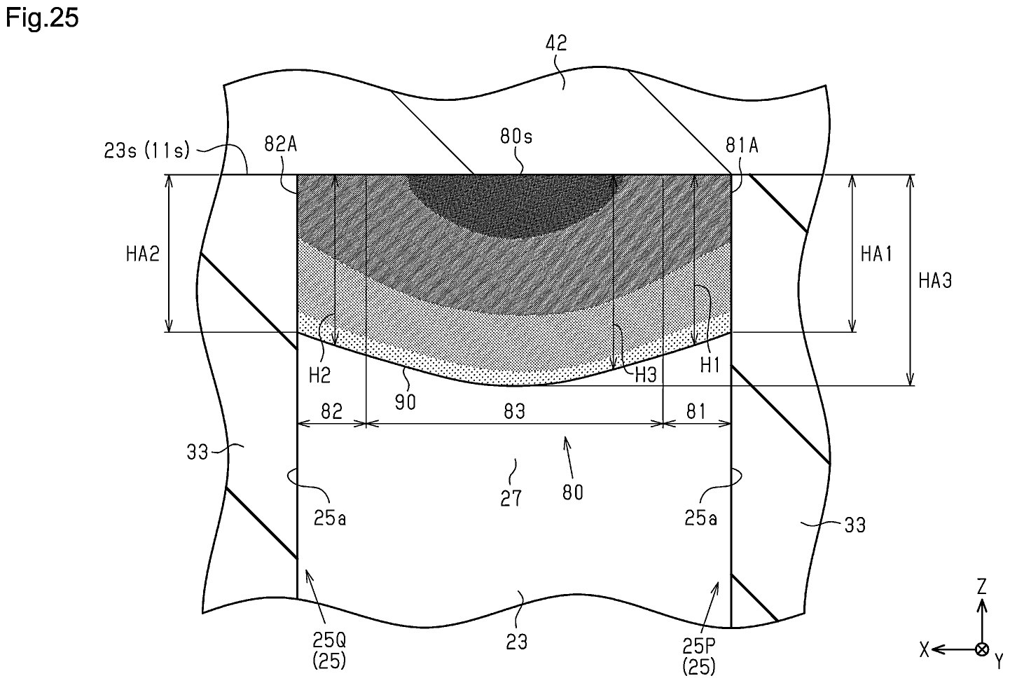

FIG. 25 is a cross-sectional view schematically showing the semiconductor device 10 of the fourth embodiment. As shown in FIG. 25, the well region 80 of the semiconductor device 10 of the fourth embodiment is formed by performing ion implantation a single time using a fourth resist mask 940 such that the ratio of the width of the opening 941 of the fourth resist mask 940 to the width of the inter-trench region 27 is greater than that of the first embodiment and less than that of the first comparative example. In the fourth embodiment, the ratio of the width of the opening 941 of the fourth resist mask 940 to the width of the inter-trench region 27 is 0.72. The width of the opening 941 is 0.5 μm. In the well region 80 of the fourth embodiment, the difference in the p-type impurity concentration between the third region 83 and the first region 81 and between the third region 83 and the second region 82 is less than that in the first embodiment. That is, the concentration gradient of the p-type impurity concentration in the well region 80 is less than that of the first embodiment.

As shown in FIG. 23, when the forward voltage drop VF is less than or equal to the predetermined voltage VX and the forward current IF has the same value, in the semiconductor device 10 of the fourth embodiment, the forward voltage drop VF is smaller than in the semiconductor device XA of the first comparative example. When the forward voltage drop VF is less than or equal to the predetermined voltage VX and the forward current IF has the same value, in the semiconductor device 10 of the first embodiment, the forward voltage drop VF is smaller than in the semiconductor device 10 of the fourth embodiment. When the forward voltage drop VF is greater than the predetermined voltage VX, the relationship of the forward voltage drop VF with the forward current IF is the same among the semiconductor devices 10 of the first embodiment and the fourth embodiment and the semiconductor device XA of the first comparative example.

As compared to the first region 81 of the well region 80 in the first embodiment, the first region 81 in the fourth embodiment has a large thickness-wise dimension HA1 of the portion 81A, which is located adjacent to the first trench 25P, and includes a region in which the p-type impurity concentration is high. As compared to the second region 82 of the well region 80 in the first embodiment, the second region 82 in the fourth embodiment has a large thickness-wise dimension HA2 of the portion 82A, which is located adjacent to the second trench 25Q, and includes a region in which the p-type impurity concentration is high. This may inhibit formation of an inversion layer in the vicinity of the insulation layers 33 of the first trench 25P and the second trench 25Q, thereby limiting an increase in the electric field intensity, in the inter-trench region 27 in the well region 80 of the fourth embodiment as compared to the well region 80 of the first embodiment. In other words, in the well region 80 of the first embodiment, an inversion layer is more likely to be formed, and the electric field intensity is more likely to be increased than in the well region 80 of the fourth embodiment.

As shown in FIG. 24, the reverse current IR slightly more readily flows in the semiconductor device 10 of the fourth embodiment than in the semiconductor device XA of the first comparative example. The reverse current IR slightly more readily flows in the semiconductor device 10 of the first embodiment than in the semiconductor device 10 of the fourth embodiment. As described above, as the concentration gradient of the p-type impurity concentration is increased in the well region 80, the reverse current IR flows slightly more readily. More specifically, the difference in the reverse current IR between the first comparative example, the first embodiment, and the fourth embodiment is in the order of 1/10000 to 1/1000. Therefore, the readiness of the reverse current IR flowing through the first comparative example, the first embodiment, and the fourth embodiment is almost the same.

### Advantages

The present embodiment has the following advantages.

(1) The semiconductor device 10 includes the n-type semiconductor substrate 21 including the substrate front surface 21s and the substrate back surface 21r opposite to the substrate front surface 21s, the n-type drift layer 23 formed on the substrate front surface 21s and including the front surface 23s, the anode electrode 42 formed on the front surface 23s of the drift layer 23, the cathode electrode 41 formed on the substrate back surface 21r, the first trench 25P and the second trench 25Q extending from the front surface 23s of the drift layer 23 in the Z-axis direction and the Y-axis direction are separated from each other in the X-axis direction, the insulation layer 33 covering the bottom wall 25b and the side walls 25a of each of the first trench 25P and the second trench 25Q, the embedded electrode 34 formed in the insulation layer 33 in contact with the anode electrode 42, and the p-type well region 80 formed in the inter-trench region 27, which is a portion of the front surface 23s of the drift layer 23 located between the first trench 25P and the second trench 25Q in the X-axis direction. The well region 80 includes the first region 81 located adjacent to the first trench 25P, the second region 82 located adjacent to the second trench 25Q, and the third region 83 located between the first region 81 and the second region 82 in the X-axis direction. Each of the first region 81 and the second region 82 is lower in p-type impurity concentration than the third region 83.

In this structure, the drift layer 23 includes the first trench 25P, the second trench 25Q, the insulation layer 33, and the embedded electrode 34. Thus, a depletion layer is formed from the positions of the first trench 25P and the second trench 25Q. Thus, the electric field intensity is reduced in the front surface 23s of the drift layer 23. This reduces the electrical resistivity of the drift layer 23, thereby reducing the forward voltage drop VF. In addition, the formation of the depletion layer from the positions of the first trench 25P and the second trench 25Q reduces the reverse current IR.

Further, due to formation of the well region 80 in the inter-trench region 27, an inversion layer is formed in the vicinity of the insulation layer 33 of the first trench 25P and the insulation layer 33 of the second trench 25Q in the inter-trench region 27. Thus, the forward voltage drop VF is reduced.

In addition, due to the low p-type impurity concentration in the first region 81, an inversion layer is likely to be formed in the vicinity of the insulation layer 33 of the first trench 25P. Due to the low p-type impurity concentration in the second region 82, an inversion layer is likely to be formed in the vicinity of the insulation layer 33 of the second trench 25Q. Thus, the forward voltage drop VF is reduced further.

Of current passages extending between the anode electrode 42 and the cathode electrode 41, current due to PN junction dominantly flows through a passage extending through the center of the inter-trench region 27 in the X-axis direction. In this regard, in the present embodiment, since the p-type impurity concentration is high in the third region 83, the electrical resistance of the current passages extending between the anode electrode 42 and the cathode electrode 41 is reduced. Thus, the forward voltage drop VF is reduced.

(2) The first region 81 or the second region 82 is lowest in p-type impurity concentration in the well region 80.

With this configuration, when the p-type impurity concentration of the first region 81 is the lowest in the well region 80, an inversion layer is more likely to be formed in the vicinity of the insulation layer 33 of the first trench 25P. When the p-type impurity concentration of the second region 82 is the lowest in the well region 80, an inversion layer is more likely to be formed in the vicinity of the insulation layer 33 of the second trench 25Q. Thus, the forward voltage drop VF is further reduced.

(3) The central portion of the third region 83 in the X-axis direction has the highest p-type impurity concentration in the well region 80.

This configuration further reduces the electrical resistance of the current passages extending between the anode electrode 42 and the cathode electrode 41. Thus, the forward voltage drop VF is further reduced.

(4) The p-type impurity concentration of the portion 81A, which is a portion of the first region 81 in contact with the first trench 25P, and the p-type impurity concentration of the portion 82A, which is a portion of the second region 82 in contact with the second trench 25Q, are each less than or equal to 1/10 of the p-type impurity concentration of the central portion of the third region 83 in the X-axis direction.

This structure improves the effect of readily forming an inversion layer in the vicinity of the insulation layer 33 of the first trench 25P, the effect of readily forming an inversion layer in the vicinity of the insulation layer 33 of the second trench 25Q, and the effect of reducing the electrical resistance of the current passage extending between the anode electrode 42 and the cathode electrode 41.

(5) The thickness-wise dimension H1 of the first region 81 and the thickness-wise dimension H2 of the second region 82 are each smaller than the thickness-wise dimension H3 of the third region 83.

This structure decreases the range in which the well region 80 is in contact with the first trench 25P and the second trench 25Q. Thus, the electric field intensity is increased in the first region 81 in the vicinity of the insulation layer 33 of the first trench 25P and in the second region 82 in the vicinity of the insulation layer 33 of the second trench 25Q, where the inversion layer is formed. In this configuration, a high electric field is applied to a current flowing through the inversion layer, which forms a channel. As a result, a channel current component is increased. Thus, the forward voltage drop VF is reduced.

(6) The first region 81 includes the portion 81A in contact with the first trench 25P. The second region 82 includes the portion 82A in contact with the second trench 25Q. The thickness-wise dimension HA1 of the portion 81A or the thickness-wise dimension HA2 of the portion 82A is the minimum value of the thickness-wise dimension of the well region 80.

This configuration further increases the electric field intensity in the vicinity of the insulation layer 33 of the first trench 25P and the insulation layer 33 of the second trench 25Q. Thus, the forward voltage drop VF is reduced.

(7) The third region 83 includes the central portion of the well region 80. The thickness-wise dimension HA3 of the central portion of the well region 80 is the maximum value of the thickness-wise dimension of the well region 80.

This configuration further reduces the electrical resistance of the current passages extending between the anode electrode 42 and the cathode electrode 41. Thus, the forward voltage drop VF is reduced.

(8) The thickness-wise dimension of the well region 80 has a maximum value that is less than or equal to ½ of the depth-wise dimension HT of the first trench 25P and the second trench 25Q.

This structure decreases the range in which the well region 80 is in contact with the first trench 25P and the second trench 25Q. Thus, the electric field intensity is increased in the vicinity of the insulation layer 33 of the first trench 25P and in the vicinity of the insulation layer 33 of the second trench 25Q, where the inversion layer is formed. This increases a channel current component, thereby reducing the forward voltage drop VF.

(9) The method for manufacturing the semiconductor device 10 includes preparing the n-type semiconductor wafer 821 including the wafer front surface 821s and the wafer back surface 821r opposite to the wafer front surface 821s, forming the n-type drift layer 823 including the front surface 823s on the wafer front surface 821s, forming the second base electrode film 840 on the front surface 823s of the drift layer 823, forming the cathode electrode 41 on the wafer back surface 821r, forming the first trench 25P and the second trench 25Q extending from the front surface 823s of the drift layer 823 in the Z-axis direction and the Y-axis direction and separated from each other in the X-axis direction, forming the insulation layer 33 covering the bottom wall 25b and the side walls 25a of the first trench 25P and the second trench 25Q, forming the embedded electrode 34, which is in contact with the second base electrode film 840, in the insulation layer 33, and forming the p-type well region 80 in the inter-trench region 27, which is a portion of the front surface 823s of the drift layer 823 located between the first trench 25P and the second trench 25Q in the X-axis direction. The well region 80 includes the first region 81 located adjacent to the first trench 25P, the second region 82 located adjacent to the second trench 25Q, and the third region 83 located between the first region 81 and the second region 82 in the X-axis direction. Each of the first region 81 and the second region 82 is lower in p-type impurity concentration than the third region 83.

In this structure, the drift layer 23 includes the first trench 25P, the second trench 25Q, the insulation layer 33, and the embedded electrode 34. Thus, a depletion layer is formed from the positions of the first trench 25P and the second trench 25Q. Thus, the electric field intensity is reduced in the front surface 23s of the drift layer 23. This reduces the electrical resistivity of the drift layer 23, thereby reducing the forward voltage drop VF. In addition, the formation of the depletion layer from the positions of the first trench 25P and the second trench 25Q reduces the reverse current IR.

Further, due to formation of the well region 80 in the inter-trench region 27, an inversion layer is formed in the vicinity of the insulation layer 33 of the first trench 25P and the insulation layer 33 of the second trench 25Q in the inter-trench region 27. Thus, the forward voltage drop VF is reduced.

In addition, due to the low p-type impurity concentration in the first region 81, an inversion layer is likely to be formed in the vicinity of the insulation layer 33 of the first trench 25P. Due to the low p-type impurity concentration in the second region 82, an inversion layer is likely to be formed in the vicinity of the insulation layer 33 of the second trench 25Q. Thus, the forward voltage drop VF is reduced further.

Of current passages extending between the anode electrode 42 and the cathode electrode 41, current due to PN junction dominantly flows through a passage extending through the center of the inter-trench region 27 in the X-axis direction. In this regard, in the present embodiment, since the p-type impurity concentration is high in the third region 83, the electrical resistance of the current passages extending between the anode electrode 42 and the cathode electrode 41 is reduced. Thus, the forward voltage drop VF is reduced.

(10) The method for manufacturing the semiconductor device 10 includes preparing the n-type semiconductor wafer 821 including the wafer front surface 821s and the wafer back surface 821r opposite to the wafer front surface 821s, forming the n-type drift layer 823 including the front surface 823s on the wafer front surface 821s, forming the second base electrode film 840 on the front surface 823s of the drift layer 823, forming the cathode electrode 41 on the wafer back surface 821r, forming the first trench 25P and the second trench 25Q extending from the front surface 823s of the drift layer 823 in the Z-axis direction and the Y-axis direction and separated from each other in the X-axis direction, forming the insulation layer 33 covering the bottom wall 25b and the side walls 25a of the first trench 25P and the second trench 25Q, forming the embedded electrode 34, which is in contact with the second base electrode film 840, in the insulation layer 33, and forming the p-type well region 80 in the inter-trench region 27, which is a portion of the front surface 823s of the drift layer 823 located between the first trench 25P and the second trench 25Q in the X-axis direction. The well region 80 includes the first region 81 located adjacent to the first trench 25P, the second region 82 located adjacent to the second trench 25Q, and the third region 83 located between the first region 81 and the second region 82 in the X-axis direction. The thickness-wise dimension H1 of the first region 81 and the thickness-wise dimension H2 of the second region 82 are each smaller than the thickness-wise dimension H3 of the third region 83.

In this structure, the drift layer 23 includes the first trench 25P, the second trench 25Q, the insulation layer 33, and the embedded electrode 34. Thus, a depletion layer is formed from the positions of the first trench 25P and the second trench 25Q. Thus, the electric field intensity is reduced in the front surface 23s of the drift layer 23. This reduces the electrical resistivity of the drift layer 23, thereby reducing the forward voltage drop VF. In addition, the formation of the depletion layer from the positions of the first trench 25P and the second trench 25Q reduces the reverse current IR.

Further, due to formation of the well region 80 in the inter-trench region 27, an inversion layer is formed in the vicinity of the insulation layer 33 of the first trench 25P and the insulation layer 33 of the second trench 25Q in the inter-trench region 27. Thus, the forward voltage drop VF is reduced.

In addition, due to the low p-type impurity concentration in the first region 81, an inversion layer is likely to be formed in the vicinity of the insulation layer 33 of the first trench 25P. Due to the low p-type impurity concentration in the second region 82, an inversion layer is likely to be formed in the vicinity of the insulation layer 33 of the second trench 25Q. Thus, the forward voltage drop VF is reduced further.

The thickness-wise dimensions H1 and H2 are each smaller than the thickness-wise dimension H3. Thus, the range in which the well region 80 is in contact with the first trench 25P and the second trench 25Q is decreased. Thus, the electric field intensity is increased in the vicinity of the insulation layer 33 of the first trench 25P and in the vicinity of the insulation layer 33 of the second trench 25Q, where the inversion layer is formed. This increases a channel current component, thereby reducing the forward voltage drop VF. The thickness-wise dimension H3 of the third region 83, which includes the central portion of the well region 80 in the X-axis direction, is relatively large. This reduces the electrical resistance of the current passages extending between the anode electrode 42 and the cathode electrode 41. Thus, the forward voltage drop VF is reduced.

(11) The forming the well region 80 includes forming the fourth resist mask 940 including the opening 941 on the front surface 823s of the drift layer 823 and implanting a p-type impurity into the inter-trench region 27 through the opening 941. In plan view, the opening 941 is smaller in width than the inter-trench region 27. The fourth resist mask 940 covers two end portions of the inter-trench region 27 in the X-axis direction, which correspond to the first region 81 and the second region 82, and exposes the central portion of the inter-trench region 27 in the X-axis direction, which corresponds to the third region 83, through the opening 941.

With this configuration, when a p-type impurity is implanted through the opening 941 into the front surface 823s of the drift layer 823, the p-type impurity diffuses from the central portion of the inter-trench region 27 in the X-axis direction in the X-axis direction and the Z-axis direction. As a result, the p-type impurity concentration decreases from the central portion of the well region 80 in the X-axis direction toward the first trench 25P and the second trench 25Q. Also, the thickness-wise dimension is decreased from the central portion of the well region 80 in the X-axis direction toward the first trench 25P and the second trench 25Q. Hence, the advantages (9) and (10) described above are obtained.

### MODIFIED EXAMPLES

The embodiments described above may be modified as follows. The above-described embodiments and the modified examples described below can be combined as long as the combined modifications remain technically consistent with each other.

The conductive type of each of the semiconductor substrate 21, the buffer layer 22, the drift layer 23, the peripheral well region 26, and the well region 80 may be reversed. More specifically, a p-type region may be changed to an n-type region, and an n-type region may be changed to a p-type region.

### Modified Examples Related to Shape of Well Region

The shape of the well region 80 may be changed in any manner. The well region 80 may be changed, for example, as shown in first to third modified examples.

In the first modified example, the ratio RH of the minimum value to the maximum value of the thickness-wise dimension of the well region 80 may be changed in any manner. For example, as shown in the fourth embodiment shown in FIG. 25, the ratio RH may be greater than 0.3. More specifically, the ratio RH is less than 1. The ratio RH may be greater than 0.5. In the example shown, the ratio RH is in a range of 0.7 to 0.8.

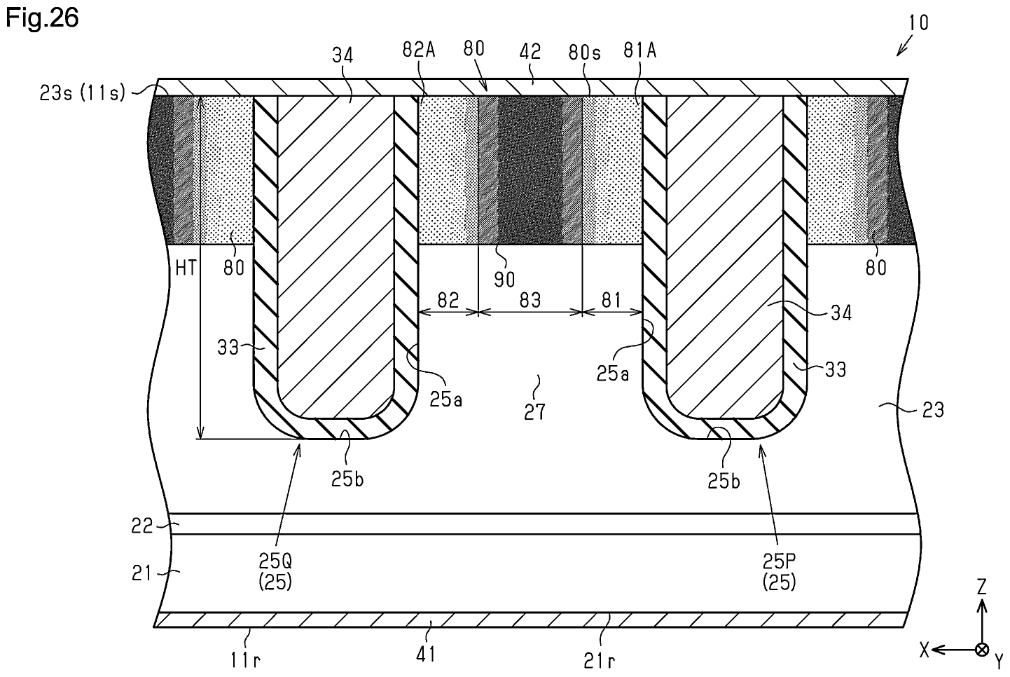

As shown in FIG. 26, in the second modified example, the thickness-wise dimension of the well region 80 is constant in the entirety of the well region 80 in the X-axis direction. That is, the interface 90 of the well region 80 and the drift layer 23 linearly extends in the X-axis direction.

In this case, for example, the p-type impurity concentration is constant in the entire portion 81A of the first region 81, which is in contact with the first trench 25P, in the Z-axis direction. That is, the entirety of the portion 81A in the Z-axis direction has the minimum value of the p-type impurity concentration in the well region 80. In another example, the p-type impurity concentration is constant in the entire portion 82A of the second region 82, which is in contact with the second trench 25Q, in the Z-axis direction. That is, the entirety of the portion 82A in the Z-axis direction has the minimum value of the p-type impurity concentration in the well region 80. In another example, the p-type impurity concentration is constant in the entire central portion of the third region 83 in the X-axis direction in the Z-axis direction. That is, the entirety, in the Z-axis direction, of the central portion of the third region 83 in the X-axis direction has the maximum value of the p-type impurity concentration in the well region 80.

In the second modified example, the p-type impurity concentration of the well region 80 may be gradually decreased as the distance from the front surface 23s of the drift layer 23 increases. In this case, the p-type impurity concentration of the lower end of the portion 81A, which is a portion of the first region 81 in contact with the first trench 25P, has the minimum value of the p-type impurity concentration in the well region 80. Alternatively, the p-type impurity concentration of the lower end of the portion 82A, which is a portion of the second region 82 in contact with the second trench 25Q, has the minimum value of the p-type impurity concentration the well region 80. The p-type impurity concentration of the upper end of the center of the third region 83 in the X-axis direction has the maximum value of the p-type impurity concentration in the well region 80.

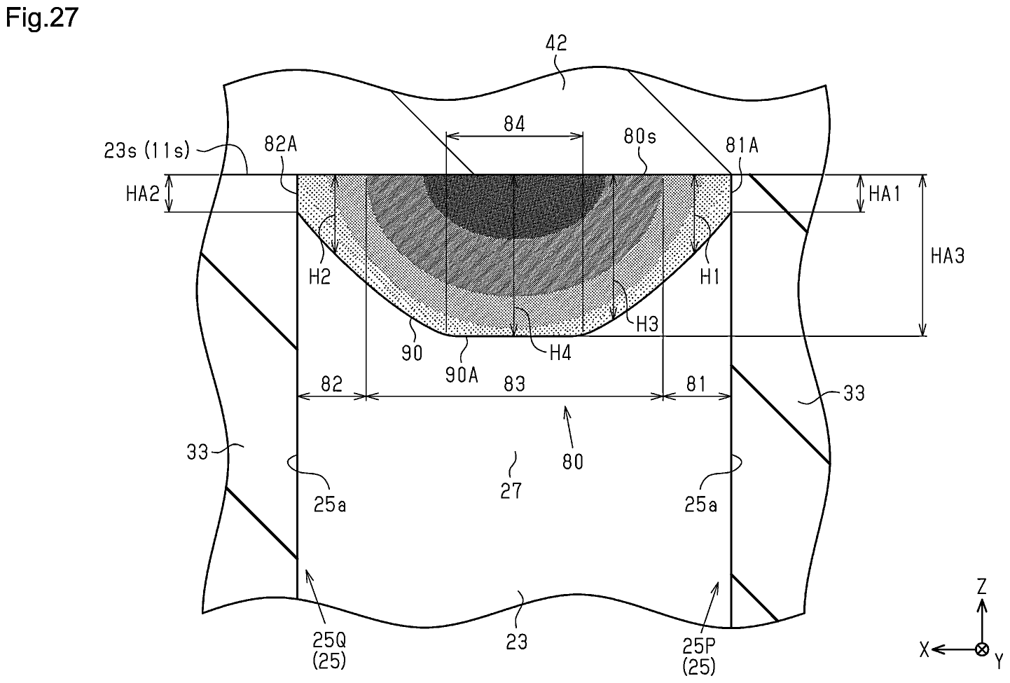

As shown in FIG. 27, in the third modified example, the thickness-wise dimension H3 of the third region 83 may be constant partially in the X-axis direction. That is, the third region 83 may include a fourth region 84 having a constant thickness-wise dimension H3. In the thickness-wise dimension H3, the thickness-wise dimension of the fourth region 84 is denoted by H4. The thickness-wise dimension H4 of the fourth region 84 is equal to the thickness-wise dimension HA3, which is the maximum value of the thickness-wise dimension H3 of the third region 83. The interface 90 between the well region 80 and the drift layer 23 may have a flat portion 90A that is flat in the X-axis direction. In the example shown, the first region 81 has a thickness that decreases from the third region 83 toward the first trench 25P. The second region 82 has a thickness that decreases from the third region 83 toward the second trench 25Q.

In the third modified example, the thickness-wise dimension H3 of the third region 83 is not limited to being constant in a portion of the third region 83 in the X-axis direction. For example, the thickness-wise dimension H3 of the third region 83 may be constant in the entirety of the third region 83 in the X-axis direction.

In the first modified example shown in FIG. 25 and the third modified example shown in FIG. 27, the concentration gradient of the p-type impurity concentration of the well region 80 may be changed in any manner. In an example, in the first modified example and the third modified example, the p-type impurity concentration may be entirely constant in the well region 80.

The first region 81 may include a region in which the thickness-wise dimension H1 of the first region 81 is constant in a range from the third region 83 to the first trench 25P.

The thickness-wise dimension H1 of the first region 81 may be constant in a range from the third region 83 to the first trench 25P.

The second region 82 may include a region in which the thickness-wise dimension H2 of the second region 82 is constant in a range from the third region 83 to the second trench 25Q.

The thickness-wise dimension H2 of the second region 82 may be constant in a range from the third region 83 to the second trench 25Q.

The thickness-wise dimension of the well region 80 may be changed in any manner. In an example, the thickness-wise dimension of the well region 80 may be greater than ½ of the depth-wise dimension HT of the trenches 25 (for example, refer to FIG. 18). In this case, the thickness-wise dimension of the well region 80 may be less than the depth-wise dimension HT of the trench 25.

### Modified Examples Related to p-Type Impurity Concentration of Well Region

The process of dividing the well region 80 into the first region 81, the second region 82, and the third region 83 may be changed in any manner. In an example, the third region 83 may be divided as a region including only the region having the highest p-type impurity concentration in the front surface 80s of the well region 80 in the X-axis direction. In this case, the width-wise dimension of the third region 83 is approximately 1.5 times the width-wise dimension of each of the first region 81 and the second region 82.

The p-type impurity concentration of the well region 80 is not limited to having the concentration gradient in the above embodiments. For example, the p-type impurity concentration of the first region 81 and the p-type impurity concentration of the second region 82 may be equal to the p-type impurity concentration of the third region 83 (for example, refer to FIG. 19). That is, the p-type impurity concentration of the well region 80 may be constant in the entirety of the well region 80.

The p-type impurity concentration of the well region 80 may be such that the p-type impurity concentration of the first region 81 and the p-type impurity concentration of the second region 82 are lower than the p-type impurity concentration of the third region 83 in the X-axis direction, and the p-type impurity concentration of the well region 80 is constant in the Z-axis direction.

The p-type impurity concentration of the first region 81 may be constant in the X-axis direction.

The p-type impurity concentration of the first region 81 may be constant in the Z-axis direction.

The p-type impurity concentration of the second region 82 may be constant in the X-axis direction.

The p-type impurity concentration of the second region 82 may be constant in the Z-axis direction.

The p-type impurity concentration of the third region 83 may be constant in the X-axis direction.

The p-type impurity concentration of the third region 83 may be constant in the Z-axis direction.

The p-type impurity concentration of the first region 81 may be higher than or lower than the p-type impurity concentration of the second region 82. When the p-type impurity concentration of the first region 81 is higher than the p-type impurity concentration of the second region 82, the p-type impurity concentration of the second region 82 is the lowest in the well region 80. When the p-type impurity concentration of the first region 81 is lower than the p-type impurity concentration of the second region 82, the p-type impurity concentration of the first region 81 is the lowest in the well region 80.

The p-type impurity concentration of the portion 81A, which is a portion of the first region 81 in contact with the first trench 25P, may be changed in any manner. In an example, the p-type impurity concentration of the portion 81A, which is a portion of the first region 81 in contact with the first trench 25P, may be greater than 1/10 of the p-type impurity concentration of the central portion of the third region 83 in the X-axis direction.

The p-type impurity concentration of the portion 82A, which is a portion of the second region 82 in contact with the second trench 25Q, may be changed in any manner. In an example, the p-type impurity concentration of the portion 82A, which is a portion of the second region 82 in contact with the second trench 25Q, may be greater than 1/10 of the p-type impurity concentration of the central portion of the third region 83 in the X-axis direction.

### Modified Examples Related to Trenches

In plan view, the trenches 25 may extend in the Y-axis direction and two of the trenches 25 adjacent to each other in the X-axis direction communicate with each other so as to be arranged in a lattice pattern. It is sufficient that each trench 25 includes a portion extending in the Y-axis direction.

As long as the isolation trench 24 is annular so as to surround the trenches 25, the isolation trench 24 may have any shape in plan view. In an example, the isolation trench 24 may include a portion that is curved in plan view and joins two trenches 25 located adjacent to each other in the X-axis direction.

### Further Embodiment

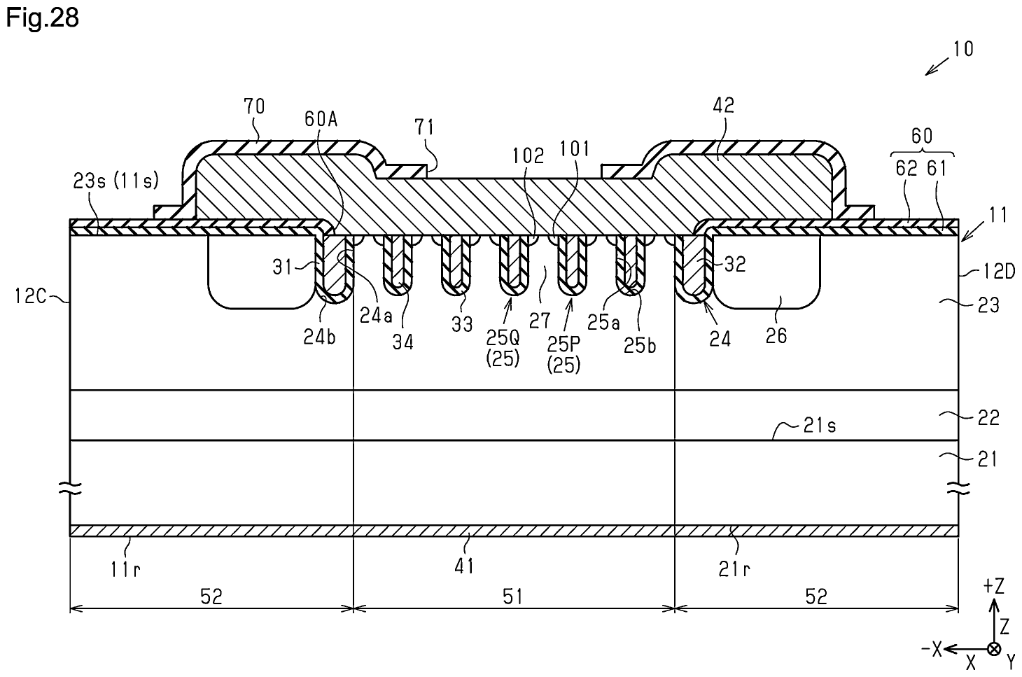

A further embodiment of the semiconductor device 10 will now be described with reference to FIGS. 28 to 30. The semiconductor device 10 of the further embodiment mainly differs from the semiconductor device 10 shown in FIGS. 1 to 5 in the configuration of the inter-trench region 27. The detailed configuration of the inter-trench region 27 will be described below. The same reference characters are given to those components that are the same as the corresponding components of the semiconductor device 10 shown in FIGS. 1 to 5. Such components will not be described in detail.

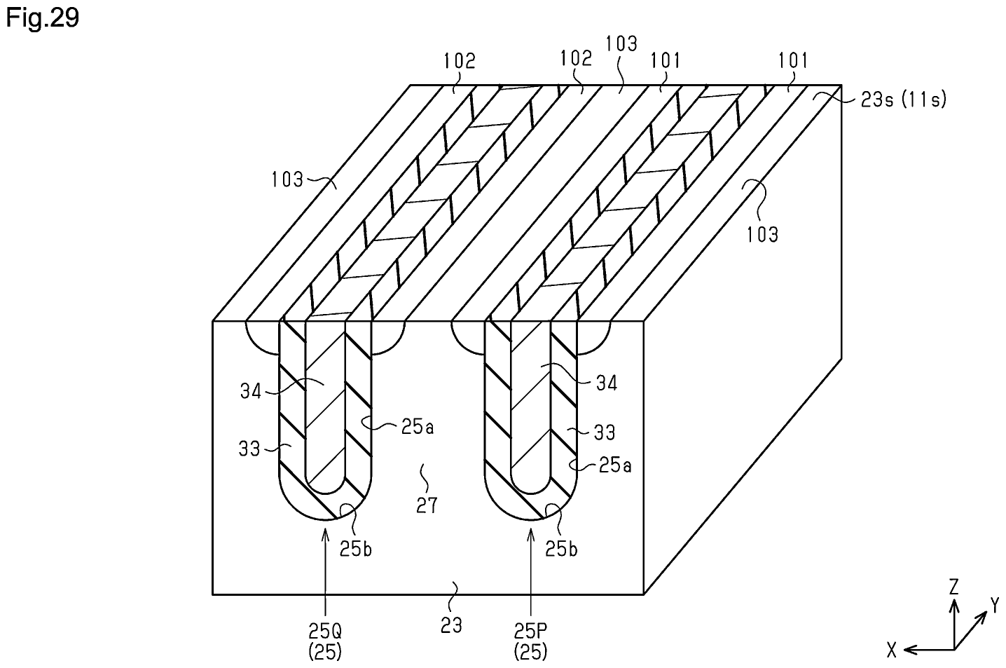

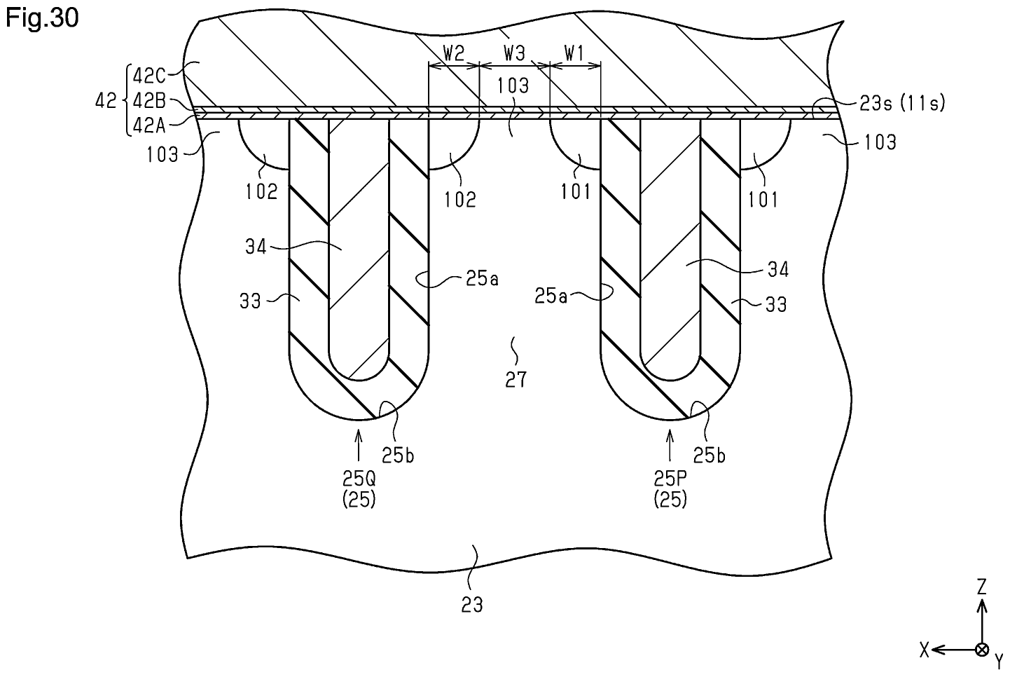

FIG. 28 is a cross-sectional view showing a structure of the semiconductor device 10 of the further embodiment corresponding to the cross-sectional structure of the above embodiment shown in FIG. 3, that is, the cross-sectional structure taken along line F3-F3 in FIG. 1. FIG. 29 is a perspective cross-sectional view schematically showing a predetermined first trench 25P and a second trench 25Q located adjacent to the first trench 25P of the semiconductor device 10 shown in FIG. 28 and surroundings of the trenches 25P and 25Q. FIG. 30 is an enlarged view of a predetermined first trench 25P and a second trench 25Q located adjacent to the first trench 25P of the semiconductor device 10 shown in FIG. 28 and surroundings of the trenches 25P and 25Q.

As shown in FIG. 28, the semiconductor device 10 includes a first well region 101 and a second well region 102 formed in the inter-trench region 27.

As shown in FIG. 30, the first well region 101 is a p-type well region located in the front surface 23s of the drift layer 23 at a position adjacent to the first trench 25P. The first well region 101 is formed in a portion of the inter-trench region 27 in the X-axis direction. In an example, as viewed in the Y-axis direction, the first well region 101 is quarter-circular. More specifically, the first well region 101 has a thickness-wise dimension that is maximum in a portion of the first well region 101 located adjacent to the first trench 25P and gradually decreases as the distance from the first trench 25P increases in the X-axis direction. In an example, the maximum value of the thickness-wise dimension of the first well region 101 is equal to the maximum value of a width-wise dimension W1 of the first well region 101 in the X-axis direction.

As shown in FIG. 29, the first well region 101 extends in the Y-axis direction. In other words, the first well region 101 extends in a direction in which the first trench 25P extends. Thus, the first well region 101 is continuously adjacent to the first trench 25P in the Y-axis direction. Thus, the first well region 101 has a length in the Y-axis direction and a width in the X-axis direction. The Y-axis direction corresponds to a “first direction.” The X-axis direction corresponds to a “second direction.”

As shown in FIG. 30, the second well region 102 is a p-type well region located in the front surface 23s of the drift layer 23 at a position adjacent to the second trench 25Q. The second well region 102 is separated from the first well region 101 in the X-axis direction. The second well region 102 is formed in a portion of the inter-trench region 27 in the X-axis direction. In an example, as viewed in the Y-axis direction, the second well region 102 is quarter-circular. More specifically, the second well region 102 has a thickness-wise dimension that is maximum in a portion of the second well region 102 located adjacent to the second trench 25Q and gradually decreases as the distance from the second trench 25Q increases in the X-axis direction. In an example, the maximum value of the thickness-wise dimension of the second well region 102 is equal to the maximum value of a width-wise dimension W2 of the second well region 102 in the X-axis direction. In an example, the maximum value of the thickness-wise dimension of the second well region 102 is equal to the maximum value of the thickness-wise dimension of the first well region 101. In an example, the maximum value of the width-wise dimension W2 of the second well region 102 is equal to the maximum value of the width-wise dimension W1 of the first well region 101. The maximum value of the width-wise dimension W2 of the second well region 102 is, for example, in a range of 0.1 μm to 10 μm. The maximum value of the width-wise dimension W1 of the first well region 101 is, for example, in a range of 0.1 μm to 10 μm.

As shown in FIG. 29, the second well region 102 extends in the Y-axis direction. In other words, the second well region 102 extends in a direction in which the second trench 25Q extends. Thus, the second well region 102 is continuously adjacent to the second trench 25Q in the Y-axis direction. The first well region 101 and the second well region 102 are arranged parallel to each other in plan view. Thus, the first well region 101 has a length in the Y-axis direction and a width in the X-axis direction.

In an example, the p-type impurity concentration of the second well region 102 is equal to the p-type impurity concentration of the first well region 101. The p-type impurity concentration of each of the first well region 101 and the second well region 102 is, for example, in a range of 1× 10¹⁶ cm⁻³ to 1×10¹⁸ cm⁻³.

As shown in FIGS. 29 and 30, the drift layer 23 includes an exposed region 103 located in the front surface 23s of the drift layer 23 between the first well region 101 and the second well region 102.

As viewed from the front surface 23s of the drift layer 23, a width-wise dimension W3 of the exposed region 103 in the X-axis direction is greater than a width-wise dimension W1 of the first well region 101 and a width-wise dimension W2 of the second well region 102. As viewed from the front surface 23s of the drift layer 23, the width-wise dimension W3 of the exposed region 103 is, for example, in a range of 0.1 μm to 10 μm. Each of the width-wise dimensions W1 to W3 is a dimension in the X-axis direction (second direction).

The relationship among the width-wise dimensions W1 to W3 of the first well region 101, the second well region 102, and the exposed region 103 may be changed in any manner in accordance with, for example, the electrical characteristics of the semiconductor device 10. In an example, as viewed from the front surface 23s of the drift layer 23, the width-wise dimension W3 of the exposed region 103 may be smaller than the width-wise dimension W1 of the first well region 101 and the width-wise dimension W2 of the second well region 102. As viewed from the front surface 23s of the drift layer 23, the width-wise dimension W3 of the exposed region 103 may be equal to the width-wise dimension W1 of the first well region 101 and the width-wise dimension W2 of the second well region 102. The shape of the first well region 101 and the second well region 102 as viewed in the Y-axis direction is not limited to a quarter circle and may be changed in any manner.

The n-type impurity concentration of the drift layer 23 is lower than the p-type impurity concentration of each of the first well region 101 and the second well region 102. Thus, the n-type impurity concentration of the exposed region 103 is lower than the p-type impurity concentration of each of the first well region 101 and the second well region 102. The n-type impurity concentration of the exposed region 103 is in a range of, for example, 1×10¹⁵ cm⁻³ to 1×10¹⁶ cm⁻³.

The anode electrode 42, which corresponds to a first electrode formed on the front surface 23s of the drift layer 23, is in ohmic contact with each of the first well region 101 and the second well region 102 in the active region 51. The anode electrode 42 is in Schottky contact with the exposed region 103.

The anode electrode 42 has a stacking structure including, for example, a first electrode film 42A, a second electrode film 42B, and a third electrode film 42C. The first electrode film 42A is in contact with the front surface 23s of the drift layer 23. The second electrode film 42B is formed on the first electrode film 42A. The third electrode film 42C is formed on the second electrode film 42B.

The first electrode film 42A may be formed from an electrode material including at least one of Mg, Al, Ti, V, Cr, Mn, Co, Ni, Cu, Zr, Nb, Mo, Pd, Ag, In, Sn, Ta, W, Pt, and Au. The first electrode film 42A may be formed of a single film or multiple films that have a stacking structure. The multiple films each may be formed from a different electrode material. In an example, the first electrode film 42A may include, for example, Mo.

The second electrode film 42B is a metal barrier film and may be formed of, for example, a Ti-based metal film. The second electrode film 42B may include at least one of Ti and TiN. The second electrode film 42B may be formed of a single film of Ti or TiN. Alternatively, the second electrode film 42B may be formed of a Ti film or a TiN film having a stacking structure. In an example, the second electrode film 42B is formed from a material including TiN.

The third electrode film 42C is configured to be an electrode pad and is formed from a material including, for example, at least one of Cu and Al. The third electrode film 42C may be formed from an electrode material including at least one of Cu, Al, AlCu, AlSi, and AlSiCu. In an example, the third electrode film 42C is formed from a material including Al.

In the semiconductor device 10 having the configuration described above, a depletion layer forms from the first well region 101 and the second well region 102. This limits leakage current as compared to, for example, a structure in which the exposed region 103 extends in the entire region between the first trench 25P and the second trench 25Q in the X-axis direction. In the exposed region 103, which forms a Schottky junction with the first electrode 42, the forward voltage is reduced as compared to, for example, a structure in which the entire region between the first trench 25P and the second trench 25Q in the X-axis direction is the first well region 101 or the second well region 102. As described above, when the first well region 101, the second well region 102, and the exposed region 103 are formed, both limitation of leakage current and reduction in forward voltage are achieved.

In the semiconductor device 10, the width-wise dimensions W1 and W2 of the first well region 101 and the second well region 102 are increased, for example, to increase the effect of limiting leakage current. The width-wise dimension W3 of the exposed region 103 is increased, for example, to increase the effect of reducing forward voltage. As described above, the width-wise dimension W1 of the first well region 101, the width-wise dimension W2 of the second well region 102, and the width-wise dimension W3 of the exposed region 103 may each be adjusted to adjust the degree of limiting leakage current and the degree of reducing forward voltage. More specifically, when the width-wise dimension W3 of the exposed region 103 is greater than the width-wise dimension W1 of the first well region 101 and the width-wise dimension W2 of the second well region 102, the effect of limiting leakage current is further increased. When the width-wise dimension W3 of the exposed region 103 is smaller than the width-wise dimension W1 of the first well region 101 and the width-wise dimension W2 of the second well region 102, that is, the width-wise dimension W1 of the first well region 101 and the width-wise dimension W2 of the second well region 102 is greater than the width-wise dimension W3 of the exposed region 103, the effect of reducing forward voltage is further increased.

In the present disclosure, the term “on” includes the meaning of “above” in addition to the meaning of “on” unless otherwise clearly indicated in the context. Therefore, the phrase “first layer formed on second layer” is intended to mean that the first layer may be formed on the second layer in contact with the second layer in one embodiment and that the first layer may be located above the second layer without contacting the second layer in another embodiment. Thus, the word “on” will also allow for a structure in which another layer is arranged between the first layer and the second layer.

The Z-axis direction as referred to in the present disclosure does not necessarily have to be the vertical direction and does not necessarily have to fully conform to the vertical direction. In the structures according to the present disclosure (e.g., the structure shown in FIG. 1), “upward” and “downward” in the Z-axis direction as referred to in the present description are not limited to “upward” and “downward” in the vertical direction. For example, the X-axis direction may be the vertical direction. Alternatively, the Y-axis direction may be the vertical direction.

In the present disclosure, “at least one of A and B” should be understood to mean “only A, only B, or both A and B.”

### Clauses

The technical aspects that are understood from the embodiment and the modified examples will be described below. To facilitate understanding without intention to limit, the reference signs of the elements in the embodiments are given to the corresponding elements in the clause with parentheses. The reference signs are used as examples to facilitate understanding, and the components in each reference sign are not limited to those components given with the reference signs.

[Clause A1] A semiconductor device (10), including:
a semiconductor substrate (21) including a substrate front surface (21s) and a substrate back surface (21r) opposite to the substrate front surface (21s), the semiconductor substrate (21) having a first conductive type;
a semiconductor layer (23) formed on the substrate front surface (21s) and including a front surface (23s), the semiconductor layer (23) having a first conductive type;
a first electrode (42) formed on the front surface (23s) of the semiconductor layer (23);
a second electrode (41) formed on the substrate back surface (21r);
a first trench (25P) and a second trench (25Q) extending from the front surface (23s) of the semiconductor layer (23) in a thickness-wise direction (Z-axis direction) of the semiconductor layer (23) and extending in a first direction (Y-axis direction) orthogonal to the thickness-wise direction (Z-axis direction) of the semiconductor layer (23), the first trench (25P) and the second trench (25Q) being separated from each other in a second direction (X-axis direction) that is orthogonal to the first direction (Y-axis direction) and the thickness-wise direction (Z-axis direction) of the semiconductor layer (23);
an insulation layer (33) covering a bottom wall (25b) and a side wall (25a) of each of the first trench (25P) and the second trench (25Q);
a third electrode (34) formed in the insulation layer (33), the third electrode (34) being in contact with the first electrode (42); and
a well region (80) formed in a portion of the front surface (23s) of the semiconductor layer (23) located between the first trench (25P) and the second trench (25Q) in the second direction (X-axis direction), the well region (80) having a second conductive type, in which
the well region (80) includes a first region (81) located adjacent to the first trench (25P), a second region (82) located adjacent to the second trench (25Q), and a third region (83) located between the first region (81) and the second region (82) in the second direction (X-axis direction), and
each of the first region (81) and the second region (82) is lower in impurity concentration than the third region (83).

[Clause A2] The semiconductor device according to clause A1, in which the first region (81) or the second region (82) is lowest in impurity concentration in the well region (80).

[Clause A3] The semiconductor device according to clause A2, in which
the third region (83) includes a central portion in the second direction (X-axis direction), and
the central portion of the third region (83) is highest in impurity concentration in the well region (80).

[Clause A4] The semiconductor device according to clause A3, in which the well region (80) has an impurity concentration that decreases from the third region (83) toward the first region (81) and the second region (82) in the second direction (X-axis direction).

[Clause A5] The semiconductor device according to clause A3 or A4, in which a portion (81A) of the first region (81) that is in contact with the first trench (25P) and a portion (82A) of the second region (82) that is in contact with the second trench (25Q) are each 1/10 or less in impurity concentration than the central portion of the third region (83) in the second direction (X-axis direction).

[Clause A6] The semiconductor device according to any one of clauses A1 to A5, in which the well region (80) has an impurity concentration that decreases as a distance from the front surface (23s) of the semiconductor layer (23) increases.

[Clause A7] The semiconductor device according to clause A6, in which the first region (81) and the second region (82) each have an impurity concentration that decreases as a distance from the front surface (23s) of the semiconductor layer (23) increases.

[Clause A8] The semiconductor device according to any one of clauses A1 to A7, in which a thickness-wise dimension of the well region (80) has a maximum value that is less than or equal to ½ of a depth-wise dimension of each of the first trench (25P) and the second trench (25Q).

[Clause A9] The semiconductor device according to any one of clauses A1 to A8, in which the first electrode (42) is in ohmic contact with the third electrode (34).

[Clause A10] A method for manufacturing a semiconductor device (10), the method including:
preparing a semiconductor substrate (21) including a substrate front surface (21s) and a substrate back surface (21r) opposite to the substrate front surface (21s), the semiconductor substrate (21) having a first conductive type;
forming a semiconductor layer (23) on the substrate front surface (21s), the semiconductor layer (23) including a front surface (23s) and having a first conductive type;
forming a first electrode (42) on the front surface (23s) of the semiconductor layer (23);
forming a second electrode (41) on the substrate back surface (21r);
forming a first trench (25P) and a second trench (25Q) extending from the front surface (23s) of the semiconductor layer (23) in a thickness-wise direction (Z-axis direction) of the semiconductor layer (23) and extending in a first direction (Y-axis direction) orthogonal to the thickness-wise direction (Z-axis direction) of the semiconductor layer (23), the first trench (25P) and the second trench (25Q) being separated from each other in a second direction (X-axis direction) that is orthogonal to the first direction (Y-axis direction) and the thickness-wise direction (Z-axis direction) of the semiconductor layer (23);
forming an insulation layer (33) covering a bottom wall (25b) and a side wall (25a) of each of the first trench (25P) and the second trench (25Q);
forming a third electrode (34) in the insulation layer (33), the third electrode (34) being in contact with the first electrode (42); and
forming a well region (80) having a second conductive type in an inter-trench region (27) that is a portion of the front surface (23s) of the semiconductor layer (23) located between the first trench (25P) and the second trench (25Q) in the second direction (X-axis direction), in which
the well region (80) includes a first region (81) located adjacent to the first trench (25P), a second region (82) located adjacent to the second trench (25Q), and a third region (83) located between the first region (81) and the second region (82) in the second direction (X-axis direction), and
each of the first region (81) and the second region (82) is lower in impurity concentration than the third region (83).

[Clause A11] The method according to clause 10, in which
the forming the well region (80) includes
   forming a mask (940) having an opening (941) on the front surface (23s) of the semiconductor layer (23), and
   implanting an impurity into the inter-trench region (27) through the opening (941), and
in plan view, the opening (941) is smaller in width than the inter-trench region (27).

[Clause A12] The method according to clause A11, in which the mask (940) covers two end portions of the inter-trench region (27) in the second direction (X-axis direction), which correspond to the first region (81) and the second region (82), and exposes a central portion of the inter-trench region (27) in the second direction (X-axis direction), which corresponds to the third region (83), through the opening (941).

[Clause A13] The method according to clause A12, in which a ratio of a width of the opening (941) to a width of the inter-trench region (27) is less than or equal to 0.8.

[Clause A14] The method according to clause A12, in which a ratio of a width of the opening (941) to a width of the inter-trench region (27) is less than or equal to 0.5.

[Clause A15] The method according to any one of clauses A11 to A14, in which an impurity is implanted into the inter-trench region (27) through the opening (941) multiple times.

[Clause A16] The method according to any one of clauses A11 to A14, in which an impurity is implanted into the inter-trench region (27) through the opening (941) a single time.

[Clause B1] A semiconductor device, including:
a semiconductor substrate (21) including a substrate front surface (21s) and a substrate back surface (21r) opposite to the substrate front surface (21s), the semiconductor substrate (21) having a first conductive type;
a semiconductor layer (23) formed on the substrate front surface (21s) and including a front surface (23s), the semiconductor layer (23) having a first conductive type;
a first electrode (42) formed on the front surface (23s) of the semiconductor layer (23);
a second electrode (41) formed on the substrate back surface (21r);
a first trench (25P) and a second trench (25Q) extending from the front surface (23s) of the semiconductor layer (23) in a thickness-wise direction (Z-axis direction) of the semiconductor layer (23) and extending in a first direction (Y-axis direction) orthogonal to the thickness-wise direction (Z-axis direction) of the semiconductor layer (23), the first trench (25P) and the second trench (25Q) being separated from each other in a second direction (X-axis direction) that is orthogonal to the first direction (Y-axis direction) and the thickness-wise direction (Z-axis direction) of the semiconductor layer (23);
an insulation layer (33) covering a bottom wall (25b) and a side wall (25a) of each of the first trench (25P) and the second trench (25Q);
a third electrode (34) formed in the insulation layer (33), the third electrode (34) being in contact with the first electrode (42); and
a well region (80) formed in a portion of the front surface (23s) of the semiconductor layer (23) located between the first trench (25P) and the second trench (25Q) in the second direction (X-axis direction), the well region (80) having a second conductive type, in which
the well region (80) includes a first region (81) located adjacent to the first trench (25P), a second region (82) located adjacent to the second trench (25Q), and a third region (83) located between the first region (81) and the second region (82) in the second direction (X-axis direction), and
the first region (81) and the second region (82) each have a thickness-wise dimension (H1, H2) that is less than a thickness-wise dimension (H3) of the third region (83).

[Clause B2] The semiconductor device according to clause B1, in which the first region (81) includes a portion (81A) in contact with the first trench (25P), the second region (82) includes a portion (82A) in contact with the second trench (25Q), and a thickness-wise dimension (HA1) of the portion (81A) of the first region (81) or a thickness-wise dimension (HA2) of the portion (82A) of the second region (82) is a minimum value of a thickness-wise dimension of the well region (80).

[Clause B3] The semiconductor device according to clause B1 or B2, in which
the third region (83) includes a central portion of the well region (80), and
a thickness-wise dimension (HA3) of the central portion of the well region (80) is a maximum value of a thickness-wise dimension of the well region (80).

[Clause B4] The semiconductor device according to any one of clauses B1 to B3, in which the first region (81) has a thickness that decreases from the third region (83) toward the first trench (25P).

[Clause B5] The semiconductor device according to clause B4, in which the second region (82) has a thickness that decreases from the third region (83) toward the second trench (25Q).

[Clause B6] The semiconductor device according to clause B4 or B5, in which the third region (83) includes a central portion of the well region (80) and has a thickness that decreases from the central portion toward the first region (81) and the second region (82).

[Clause B7] The semiconductor device according to any one of clauses B4 to B6, in which an interface (90) between the well region (80) and the semiconductor layer (23) is convex toward the semiconductor substrate (21) as a distance from each of the first trench (25P) and the second trench (25Q) increases in the second direction (X-axis direction).

[Clause B8] The semiconductor device according to any one of clauses B1 to B7, in which a ratio of the minimum value to the maximum value of the thickness-wise dimension of the well region (80) is in a range of 0.1 to 0.3.

[Clause B9] The semiconductor device according to any one of clauses B1 to B8, in which a thickness-wise dimension of the well region (80) has a maximum value that is less than or equal to ½ of a depth-wise dimension (HT) of the first trench (25P) and the second trench (25Q).

[Clause B10] The semiconductor device according to any one of clauses B1 to B9, in which the first electrode (42) is in ohmic contact with the third electrode (34).

[Clause B11] The semiconductor device according to any one of clauses B1 to B10, in which each of the first region (81) and the second region (82) is lower in impurity concentration than the third region (83).

[Clause B12] The semiconductor device according to any one of clauses B1 to B10, in which the first region (81), the second region (82), and the third region (83) are equal to each other in impurity concentration.

[Clause B13] A method for manufacturing a semiconductor device, the method including:
preparing a semiconductor substrate (21) including a substrate front surface (21s) and a substrate back surface (21r) opposite to the substrate front surface (21s), the semiconductor substrate (21) having a first conductive type;
forming a semiconductor layer (23) on the substrate front surface (21s), the semiconductor layer (23) including a front surface (23s) and having a first conductive type;
forming a first electrode (42) on the front surface (23s) of the semiconductor layer (23);
forming a second electrode (41) on the substrate back surface (21r);
forming a first trench (25P) and a second trench (25Q) extending from the front surface (23s) of the semiconductor layer (23) in a thickness-wise direction (Z-axis direction) of the semiconductor layer (23) and extending in a first direction (Y-axis direction) orthogonal to the thickness-wise direction (Z-axis direction) of the semiconductor layer (23s), the first trench (25P) and the second trench (25Q) being separated from each other in a second direction (X-axis direction) that is orthogonal to the first direction (Y-axis direction) and the thickness-wise direction (Z-axis direction) of the semiconductor layer (23);
forming an insulation layer (33) covering a bottom wall (25b) and a side wall (25a) of each of the first trench (25P) and the second trench (25Q);
forming a third electrode (34) in the insulation layer (33), the third electrode (34) being in contact with the first electrode (42); and
forming a well region (80) having a second conductive type in an inter-trench region (27) that is a portion of the front surface (23s) of the semiconductor layer (23) located between the first trench (25P) and the second trench (25Q) in the second direction (X-axis direction), in which
the well region (80) includes a first region (81) located adjacent to the first trench (25P), a second region (82) located adjacent to the second trench (25Q), and a third region (83) located between the first region (81) and the second region (82) in the second direction (X-axis direction), and
the first region (81) and the second region (82) each have a thickness-wise dimension (H1, H2) that is smaller than a thickness-wise dimension (H3) of the third region (83).

[Clause B14] The method according to clause B13, in which
the forming the well region (80) includes
   forming a mask (940) having an opening (941) on the front surface (23s) of the semiconductor layer (23), and
   implanting an impurity into the inter-trench region (27) through the opening (941), and
in plan view, the opening (941) is smaller in width than the inter-trench region (27).

[Clause B15] The method according to clause B14, in which the mask (940) covers two end portions of the inter-trench region (27) in the second direction (X-axis direction), which correspond to the first region (81) and the second region (82), and exposes a central portion of the inter-trench region (27) in the second direction (X-axis direction), which corresponds to the third region (83), through the opening (941).

[Clause B16] The method according to clause B15, in which a ratio of a width of the opening (941) to a width of the inter-trench region (27) is less than or equal to 0.8.

[Clause B17] The method according to clause B15, in which a ratio of a width of the opening (941) to a width of the inter-trench region (27) is less than or equal to 0.5.

[Clause B18] The method according to any one of clauses B14 to B17, further including:
implanting an impurity into the inter-trench region (27) through the opening (941) multiple times.

[Clause B19] The method according to any one of clauses B14 to B17, further including:
implanting an impurity into the inter-trench region (27) through the opening (941) a single time.

[Clause B20] The semiconductor device according to any one of clauses B1 to B5, in which
the third region (83) includes a fourth region (84) having a constant thickness, and
the fourth region (84) has a thickness-wise dimension (H4) that is greater than a maximum value of a thickness-wise dimension (H1) of the first region (81) and a maximum value of a thickness-wise dimension (H2) of the second region (82).

[Clause C1] A semiconductor device (10), including:
a semiconductor substrate (21) including a substrate front surface (21s) and a substrate back surface (21r) opposite to the substrate front surface (21s), the semiconductor substrate (21) having a first conductive type;
a semiconductor layer (23) formed on the substrate front surface (21s) and including a front surface (23s), the semiconductor layer (23) having a first conductive type;
a first electrode (42) formed on the front surface (23s) of the semiconductor layer (23);
a second electrode (41) formed on the substrate back surface (21r);
a first trench (25P) and a second trench (25Q) extending from the front surface (23s) of the semiconductor layer (23) in a thickness-wise direction (Z-axis direction) of the semiconductor layer (23) and extending in a first direction (Y-axis direction) orthogonal to the thickness-wise direction (Z-axis direction) of the semiconductor layer (23), the first trench (25P) and the second trench (25Q) being separated from each other in a second direction (X-axis direction) that is orthogonal to the first direction (Y-axis direction) and the thickness-wise direction (Z-axis direction) of the semiconductor layer (23);
an insulation layer (33) covering a bottom wall (25b) and a side wall (25a) of each of the first trench (25P) and the second trench (25Q);
a third electrode (34) formed in the insulation layer (33), the third electrode (34) being in contact with the first electrode (42);
a first well region (101) located in the front surface (23s) of the semiconductor layer (23) at a position adjacent to the first trench (25P), the first well region (101) having a second conductive type; and
a second well region (102) located in the front surface (23s) of the semiconductor layer (23) at a position adjacent to the second trench (25Q) and separated from the first well region (101) in the second direction (X-axis direction), in which
the semiconductor layer (23) includes an exposed region (103) located in the front surface (23s) between the first well region (101) and the second well region (102), and
the first electrode (42) is in ohmic contact with each of the first well region (101) and the second well region (102) and is in Schottky contact with the exposed region (103).

[Clause C2] The semiconductor device according to clause C1, in which the exposed region (103) is lower in impurity concentration than each of the first well region (101) and the second well region (102).

[Clause C3] The semiconductor device according to clause C1 or C2, in which a dimension (W3) of the exposed region (103) in the second direction (X-axis direction) is greater than a dimension (W1) of the first well region (101) in the second direction (X-axis direction) and a dimension (W2) of the second well region (102) in the second direction (X-axis direction).

[Clause C4] The semiconductor device according to clause C1 or C2, in which a dimension (W3) of the exposed region (103) in the second direction (X-axis direction) is smaller than a dimension (W1) of the first well region (101) in the second direction (X-axis direction) and a dimension (W2) of the second well region (102) in the second direction (X-axis direction).

[Clause C5] The semiconductor device according to any one of clauses C1 to C4, in which the first well region (101) and the second well region (102) each extend in the first direction (Y-axis direction).

[Clause C6] The semiconductor device according to any one of clauses C1 to C5, in which the exposed region (103) has a dimension (W3) in the second direction (X-axis direction) that is in a range of 0.1 μm to 10 μm.

[Clause C7] The semiconductor device according to any one of clauses C1 to C6, in which the first well region (101) and the second well region (102) each have a dimension (W1, W2) in the second direction (X-axis direction) that is in a range of 0.1 μm to 10 μm.

The description above illustrates examples. One skilled in the art may recognize further possible combinations and replacements of the components and methods (manufacturing processes) in addition to those listed for purposes of describing the techniques of the present disclosure. The present disclosure is intended to include any substitute, modification, changes included in the scope of the disclosure including the claims.

### REFERENCE SIGNS LIST

10) semiconductor device
11) semiconductor chip
11s) front surface
11r) back surface
12A to 12D) first to fourth chip side surfaces
21) semiconductor substrate
21s) substrate front surface
21r) substrate back surface
22) buffer layer
23) drift layer
23s) front surface
24) isolation trench
24a) side wall
24b) bottom wall
25) trench
25P) first trench
25Q) second trench
25a) side wall
25b) bottom wall
26) peripheral well region
27) inter-trench region
31) isolation insulation film
32) isolation electrode
33) insulation layer
34) embedded electrode
41) cathode electrode
42) anode electrode
42A) first electrode film
42B) second electrode film
42C) third electrode film
51) active region
52) peripheral region
60) surface insulation layer
60A) through hole
61) first insulation film
62) second insulation film
70) surface protection layer
71) opening
80) well region
80s) front surface
80XA) well region of first comparative example
80XB) well region of second comparative example
81) first region
81A) portion in contact with first trench
81B) portion located adjacent to third region
82) second region
82A) portion in contact with second trench
82B) portion located adjacent to third region
83) third region
84) fourth region
90) interface between well region and drift region
90A) flat portion
101) first well region
102) second well region
103) exposed region
821) semiconductor wafer
821s) wafer front surface
821r) wafer back surface
822) buffer layer
823) drift layer
823s) front surface
830) first base electrode film
840) second base electrode film
850) first base insulation film
860) second base insulation film
861) through hole
900) mask
901) opening
910) first resist mask
911) opening
920) second resist mask
921) opening
930) third resist mask
931) opening
940) fourth resist mask
941) opening
XA) semiconductor device in first comparative example
XB) semiconductor device in second comparative example
P1, P2) position
CL) cutting line
H1) thickness-wise dimension of first region
HA1) thickness-wise dimension of portion of first region in contact with first trench
H2) thickness-wise dimension of second region
HA2) thickness-wise dimension of portion of second region in contact with second trench
H3) thickness-wise dimension of third region
HA3) thickness-wise dimension of central portion of well region
H4) thickness-wise dimension of fourth region
HT) depth-wise dimension of trench

1. A semiconductor device, comprising:
a semiconductor substrate including a substrate front surface and a substrate back surface opposite to the substrate front surface, the semiconductor substrate having a first conductive type;
a semiconductor layer formed on the substrate front surface and including a front surface, the semiconductor layer having a first conductive type;
a first electrode formed on the front surface of the semiconductor layer;
a second electrode formed on the substrate back surface;
a first trench and a second trench extending from the front surface of the semiconductor layer in a thickness-wise direction of the semiconductor layer and extending in a first direction orthogonal to the thickness-wise direction of the semiconductor layer, the first trench and the second trench being separated from each other in a second direction that is orthogonal to the first direction and the thickness-wise direction of the semiconductor layer;
an insulation layer covering a bottom wall and a side wall of each of the first trench and the second trench;
a third electrode formed in the insulation layer, the third electrode being in contact with the first electrode; and
a well region formed in a portion of the front surface of the semiconductor layer located between the first trench and the second trench in the second direction, the well region having a second conductive type, wherein
the well region includes a first region located adjacent to the first trench, a second region located adjacent to the second trench, and a third region located between the first region and the second region in the second direction, and
each of the first region and the second region is lower in impurity concentration than the third region.

2. The semiconductor device according to claim 1, wherein the first region or the second region is lowest in impurity concentration in the well region.

3. The semiconductor device according to claim 2, wherein
the third region includes a central portion in the second direction, and
the central portion of the third region is highest in impurity concentration in the well region.

4. The semiconductor device according to claim 3, wherein the well region has an impurity concentration that decreases from the third region toward the first region and the second region in the second direction.

5. The semiconductor device according to claim 3, wherein a portion of the first region that is in contact with the first trench and a portion of the second region that is in contact with the second trench are each 1/10 or less in impurity concentration than the central portion of the third region in the second direction.

6. The semiconductor device according to claim 1, wherein the well region has an impurity concentration that decreases as a distance from the front surface of the semiconductor layer increases.

7. The semiconductor device according to claim 6, wherein the first region and the second region each have an impurity concentration that decreases as a distance from the front surface of the semiconductor layer increases.

8. The semiconductor device according to claim 1, wherein a thickness-wise dimension of the well region has a maximum value that is less than or equal to ½ of a depth-wise dimension of each of the first trench and the second trench.

9. The semiconductor device according to claim 1, wherein the first electrode is in ohmic contact with the third electrode.

10. A semiconductor device, comprising:
a semiconductor substrate including a substrate front surface and a substrate back surface opposite to the substrate front surface, the semiconductor substrate having a first conductive type;
a semiconductor layer formed on the substrate front surface and including a front surface, the semiconductor layer having a first conductive type;
a first electrode formed on the front surface of the semiconductor layer;
a second electrode formed on the substrate back surface;
a first trench and a second trench extending from the front surface of the semiconductor layer in a thickness-wise direction of the semiconductor layer and extending in a first direction orthogonal to the thickness-wise direction of the semiconductor layer, the first trench and the second trench being separated from each other in a second direction that is orthogonal to the first direction and the thickness-wise direction of the semiconductor layer;
an insulation layer covering a bottom wall and a side wall of each of the first trench and the second trench;
a third electrode formed in the insulation layer, the third electrode being in contact with the first electrode;
a first well region located in the front surface of the semiconductor layer at a position adjacent to the first trench, the first well region having a second conductive type; and
a second well region located in the front surface of the semiconductor layer at a position adjacent to the second trench and separated from the first well region in the second direction, wherein
the semiconductor layer includes an exposed region located in the front surface between the first well region and the second well region, and
the first electrode is in ohmic contact with each of the first well region and the second well region and is in Schottky contact with the exposed region.

11. The semiconductor device according to claim 10, wherein the exposed region is lower in impurity concentration than each of the first well region and the second well region.

12. The semiconductor device according to claim 10, wherein a dimension of the exposed region in the second direction is greater than a dimension of the first well region in the second direction and a dimension of the second well region in the second direction.

13. The semiconductor device according to claim 10, wherein a dimension of the exposed region in the second direction is smaller than a dimension of the first well region in the second direction and a dimension of the second well region in the second direction.

14. A method for manufacturing a semiconductor device, the method comprising:
preparing a semiconductor substrate including a substrate front surface and a substrate back surface opposite to the substrate front surface, the semiconductor substrate having a first conductive type;
forming a semiconductor layer on the substrate front surface, the semiconductor layer including a front surface and having a first conductive type;
forming a first electrode on the front surface of the semiconductor layer;
forming a second electrode on the substrate back surface;
forming a first trench and a second trench extending from the front surface of the semiconductor layer in a thickness-wise direction of the semiconductor layer and extending in a first direction orthogonal to the thickness-wise direction of the semiconductor layer, the first trench and the second trench being separated from each other in a second direction that is orthogonal to the first direction and the thickness-wise direction of the semiconductor layer;
forming an insulation layer covering a bottom wall and a side wall of each of the first trench and the second trench;
forming a third electrode in the insulation layer, the third electrode being in contact with the first electrode; and
forming a well region having a second conductive type in an inter-trench region that is a portion of the front surface of the semiconductor layer located between the first trench and the second trench in the second direction, wherein
the well region includes a first region located adjacent to the first trench, a second region located adjacent to the second trench, and a third region located between the first region and the second region in the second direction, and
each of the first region and the second region is lower in impurity concentration than the third region.

15. The method according to claim 14, wherein
the forming the well region includes
forming a mask having an opening on the front surface of the semiconductor layer,
implanting an impurity into the inter-trench region through the opening, and
in plan view, the opening is smaller in width than the inter-trench region.

16. The method according to claim 15, wherein the mask covers two end portions of the inter-trench region in the second direction, which correspond to the first region and the second region, and exposes a central portion of the inter-trench region in the second direction, which corresponds to the third region, through the opening.

17. The method according to claim 16, wherein a ratio of a width of the opening to a width of the inter-trench region is less than or equal to 0.8.

18. The method according to claim 16, wherein a ratio of a width of the opening to a width of the inter-trench region is less than or equal to 0.5.

19. The method according to claim 15, wherein an impurity is implanted into the inter-trench region through the opening multiple times.

20. The method according to claim 15, wherein an impurity is implanted into the inter-trench region through the opening a single time.
